(19) United States
(12) Patent Application Publication
(10) Pub. No.: US 2020/0381276 A1
(43) Pub. Date: Dec. 3, 2020

(54) MULTISUBSTRATE PROCESS SYSTEM

(71) Applicant: Applied Materials, Inc., Santa Clara, CA (US)

(72) Inventors: Srinivasa Rao YEDLA, Bangalore (IN); Kirankumar Neelasandra SAVANDAIAH, Bangalore (IN); Thomas BREZOCZKY, Los Gatos, CA (US); Bhaskar PRASAD, Adityapur (IN); Shashikanth CHENNAKESHAVA, Chikmagalur (IN); Sreenath SOVENAHALLI, Bangalore (IN); Shankar KODLE, Bangalore (IN)

(21) Appl. No.: 16/877,357

(22) Filed: May 18, 2020

Related U.S. Application Data
(63) Continuation-in-part of application No. 16/427,642, filed on May 31, 2019.

(51) Int. Cl. H01L 21/67; H01L 21/687; B25J 15/00; B25J 9/04; B25J 11/00

(52) U.S. Cl. CPC H01L 21/67167; H01L 21/6719; H01L 21/67207; B25J 11/0095; B25J 15/0014; B25J 15/0052; B25J 9/041; H01L 21/68707

(57) ABSTRACT

Aspects of the disclosure provided herein generally provide a substrate processing system that includes at least one processing module that includes a plurality of process stations coupled thereto and a substrate transferring device disposed within a transfer region of the processing module for transferring a plurality of substrates to two or more of the plurality of process stations. The methods and apparatuses disclosed herein are useful for performing vacuum processing on substrates wherein one or more substrates are transferred within the transfer region of processing module that is in direct communication with at least a portion of a processing region of a plurality of separately isolatable process stations during the process of transferring the one or more substrates. In some embodiments, a substrate is positioned and maintained on the same substrate support member during the process of transferring the substrate within the processing module and while the substrate is being processed in each of the plurality of process stations.

### CROSS-REFERENCE TO RELATED APPLICATIONS

This application is a Continuation-In-Part of U.S. patent application Ser. No. 16/427,642, filed May 31, 2019, which is incorporated by reference in its entirety.

### FIELD

The present disclosure relates to an apparatus and method of processing substrates in a sub-atmospheric pressure environment. More particularly, the present disclosure relates to the deposition of thin films on a substrate in a vacuum environment, the removal of all or a portion of a thin film from a substrate in a vacuum environment, or the performance of other processes on a substrate in a vacuum environment.

### BACKGROUND

Deposition and dry etch processes are used to form layers on, and remove all or a portion of one or more layers from, a substrate. For example, it is known to deposit thin metal and dielectric films on substrates, such as directly on a semiconductor substrate or on film layers already formed thereon, using a sputtering process, also known as physical vapor deposition or “PVD”. In PVD, a vacuum chamber holds a target and a substrate support having a substrate thereon, and the target, composed of a metal or a dielectric, is negatively charged and exposed to an inert gas plasma to cause plasma formed gas ions to bombard the target and sputter material therefrom such that at least a portion of that material is deposited on the substrate. In the fabrication of semiconductor devices such as integrated circuits, PVD is commonly used to deposit materials, such as metal films, metal oxides and metal nitrides on a semiconductor substrate, or on film layers previously formed thereon. The deposited materials can then be further processed into metallic studs known as contacts or vias, or into lines used to interconnect active regions on or in the underlying semiconductor substrate. For the deposition of metal oxides and metal nitrides, an oxygen or nitrogen gas is added to the inert plasma gas, and the N or O atoms therein react with the sputtered metal to result in the metal oxide or metal nitride film being deposited on the substrate or a film layer thereon. PVD is also used to deposit layers, including non-metallic layers, which are used to define features in underlying film layers. For example, the PVD process is used to deposit patterning films, which are then patterned using a photoresist application and developing process, photolithography, and etching, to allow etching of an underlying film using an etchant to remove material exposed in openings in the patterning layer, as well as to deposit anti-reflective coatings, materials used to form hard masks and other useful materials.

Another method of forming a thin film on a substrate is commonly referred to as chemical vapor deposition, or “CVD”. In a CVD process, a substrate is loaded into a vacuum chamber, and one or more chemical precursors having the components of a thin film to be formed on the substrate are introduced into the vacuum chamber. Deposition of the thin film on the substrate, or on a layer thereon, occurs by one or more of a thermal reaction where the temperature of the substrate is sufficient to cause the precursor to decompose and leave behind one or more atoms of the thin film material to be deposited, by reaction of the chemical precursors with each other, at the substrate surface, over the substrate surface, or both, to form and leave on the substrate surface an atom or molecule of the thin film material to be deposited as a result of the reaction. To speed the reaction, or even initiate the reaction, a plasma or electromagnetic energy may be used to cause the material to be to be deposited on the substrate to be formed by reaction with the substrate surface, on the surface of a film layer thereon, over the substrate, or combinations thereof.

Dry etching, commonly used in semiconductor processing to form features in a substrate, or in one or more thin films on the substrate is typically a reactive ion etch process. Here, a plasma composed of an inert gas and one or more etching gases is formed in a vacuum chamber, and the material underlying a patterned mask layer is exposed to etching reactants in the plasma, while the substrate or substrate support is negatively biased to also cause ions in the plasma to physically remove material of the underlying layer exposed through the openings in the mask layer. Etching radicals are simultaneously created from the etching gas in the plasma to chemically interact with and chemically etch the material of the underlying layer exposed through the openings in the mask layer.

Many thin film deposition and etch processes used in semiconductor and flat panel display production employ single substrate processing chambers that are attached to a mainframe of a cluster tool, wherein a single substrate is loaded into a dedicated vacuum process chamber having dedicated hardware therein to support the substrate during a process performed thereon. The time required to load and unload the substrate from the dedicated chamber using a robot that is able to pick up and transfer one wafer at a time, which commonly includes the time needed to chuck and de-chuck the substrate from the substrate support in each process chamber, adds overhead time to the total time required to process a substrate in a cluster tool, decreases throughput and increases cost of ownership (CoO).

While the conventional cluster tool designs are suitable for processing a substrate or multiple substrates, the inventors have found that such cluster tools, can be limited in mechanical throughput, are unable to achieve desired vacuum levels, have reduced processing flexibility, can have a relatively large footprint, are relatively expensive to manufacture, have a large number of redundant parts and/or have a high cost-of-ownership.

Therefore, there is a need for a system and a method of processing a substrate that solves the problems described above.

### SUMMARY

A substrate processing system disclosed herein includes a processing module including a base, a perimeter wall and an upper wall overlying the base and defining an access space therebetween, a robot including at least one arm extending from a central location within the access space and an end effector disposed on an end of the arm distal to the central location within the access space, the arm pivotable about the central location to move the end effector thorough an orbital path, at least one process station disposed on the orbital path, and including a substrate support lift and a process volume, and a substrate support, the substrate support positionable on the end effector to be moved along the orbital path thereby, and on the substrate support lift to be moved into engagement with a portion of the process volume.

Embodiments of the disclosure provided herein include substrate processing system, comprising a processing module comprising a plurality of walls that at least partially define a transfer region, wherein the plurality of walls comprise a first wall that comprises an array of process station openings that surround a central axis, and a second wall comprising a central opening, wherein the second wall is positioned on a side of the processing module that is opposite to the first wall, two or more process stations positioned on the first wall, wherein each process station of the two or more process stations is separately disposed over a process station opening, a central robot that is configured to transfer substrates within the transfer region, and a plurality of substrate supports that each comprise a sealing surface and a body that has a substrate receiving surface and one or more electrical elements disposed therein. The two or more process stations may each comprise a source assembly, a process kit assembly that comprises a plurality of processing region components and a sealing assembly, and a substrate support actuation assembly that comprises a support plate assembly that is positionable by an actuator that is coupled to the second wall. The central robot comprises a plurality of support arms that are coupled to a central support at a first end, and include a supporting region at a second end, and an actuator configured to rotate the central support and the plurality of support arms about the central axis, wherein the supporting region of each support arm is positionable below a process station opening as the support arm is rotated about the central axis. A substrate support is disposed on a supporting region of each of the support arms when substrates are being transferred in the transfer region by the central robot, and the substrate support is disposed on a support plate assembly, and separated from the supporting region of the support arm, when a substrate is positioned in a processing position within a process station of the two or more process stations by the actuator.

Embodiments of the disclosure may further provide a substrate processing system, comprising a processing module comprising a plurality of walls that at least partially define a transfer region, wherein the plurality of walls comprises a first wall that comprises a first central opening and an array of process station openings that surround the first central opening, and a second wall comprising a second central opening, wherein the second wall is positioned on a side of the processing module that is opposite to first wall, two or more process stations positioned on the first wall, wherein each process station of the two or more process stations is separately disposed over a process station opening, and a structural support assembly. The two or more process stations comprise a source assembly that comprises a processing surface that is adjacent to a processing region of the process station and is positioned in a parallel relationship to a horizontal plane. The structural support assembly comprises a support element having a toroidal shape and mounting surface, and an array of mounting elements that are disposed between the supporting element and the first wall of the processing module. Each of the mounting elements comprise a first end that is coupled to the first wall at a radial position on a radial line that extends between two adjacent process station openings of the array of process station openings, and a second end that is coupled to the mounting surface of the support element. The structural support assembly is configured to reduce the deflection of the first wall and angular misalignment of the processing surface to the horizontal plane when a vacuum pressure is generated in the transfer region. The substrate processing system disclosed herein may further comprise a physical vapor deposition (PVD) target, and thus the processing surface can be defined by a surface of the physical vapor deposition (PVD) target. The substrate processing system disclosed herein can include a source assembly that comprises a showerhead, and the processing surface is defined by a surface of the showerhead.

Embodiments of the disclosure may further provide a substrate processing system, comprising a processing module comprising a plurality of walls that at least partially define a transfer region, wherein the plurality of walls comprises a first wall that comprises a first central opening and an array of upper process station openings that surround the first central opening, and a second wall comprising a second central opening and an array of lower process station openings that surround the second central opening, wherein the second wall is positioned on a side of the processing module that is opposite to first wall, a central robot, two or more process stations positioned on the first wall, wherein each process station is disposed over one of the upper process station openings, and a substrate support. The central robot comprises a central support that is positioned over the second central opening and within the transfer region, a plurality of support arms that are coupled to central support and extend from the central support in a radial direction that extends from a central axis, and an actuator configured to rotate the central support and the plurality of support arms about the central axis. Each of the two or more process stations may comprise a source assembly, and a process kit assembly that comprises a plurality of processing region components and a sealing assembly, and a substrate support actuation assembly that comprises an actuator that is coupled to the second wall. The substrate support comprises a body that has a substrate receiving surface and one or more electrical elements disposed therein, and the substrate support is configured to be transferred from a transfer position to a process position by use of the actuator of the substrate support actuation assembly, wherein the transfer position is positioned below the plurality of support arms and the process position is positioned above the plurality of support arms.

Embodiments of the disclosure may further provide substrate processing system, comprising a processing module comprising a plurality of walls that at least partially define a transfer region, wherein the plurality of walls comprises a first wall that comprises a first central opening and an array of process station openings that surround the first central opening, and a second wall comprising a second central opening, wherein the second wall is positioned on a side of the processing module that is opposite to first wall, a central robot, two or more process stations positioned on the first wall, wherein each process station is separately disposed over a process station opening, and substrate support. The central robot comprises a central support that is positioned over the second central opening and within the transfer region, a plurality of support arms that are coupled to the central support and extend from the central support in a radial direction which extends from a central axis, and an actuator configured to rotate the central support and the plurality of support arms about the central axis. Each of the two or more process stations comprise a source assembly, and a process kit assembly that comprises a plurality of processing region components and a sealing assembly, and a substrate support actuation assembly that comprises an actuator. The substrate support comprises a sealing surface and a body that has a substrate receiving surface and one or more electrical elements disposed therein, wherein the substrate support is configured to be positioned in a process position that is positioned vertically above the plurality of support arms by the actuator of the substrate support actuation assembly, and the sealing surface is configured to contact a surface of the sealing assembly when the substrate support is positioned in the process position, and cause a processing region to be fluidly isolated from the transfer region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a partial sectional view of a substrate that has a plurality of film layers deposited thereon that are formed and/or processed by use of a method and/or apparatus disclosed herein.

FIG. 1B is a partial sectional view of a substrate that has a feature formed thereon that is covered, lined and filled with layers of deposited material formed and/or processed by use of a method and/or apparatus disclosed herein.

FIG. 2A is a plan view of a processing system that includes a processing module that includes process stations therein for processing substrates, according to one or more embodiments.

FIG. 2B is a plan view of an alternative version of a processing system that includes a plurality of processing modules that each include process stations therein for processing substrates, according to one or more embodiments.

FIG. 3A is an isometric view of the processing module of FIG. 2A, according to one or more embodiments

FIG. 3B is a plan view of the processing module of FIG. 2A, according to one or more embodiments.

FIG. 4A is a partial sectional view of a portion of the processing module of FIG. 2A, showing a substrate support in a transfer position below a process station of the processing module, according to one or more embodiments.

FIG. 4B is a partial cross-sectional view of the processing module of FIG. 2A, showing a substrate support lifted into a process position to form a sealed substrate process volume therewith, according to one or more embodiments.

FIG. 4C is a partial sectional view of a portion of the processing module of FIG. 2A, showing an alternate configuration of a substrate support in a transfer position below a process station of the processing module, according to one or more embodiments.

FIG. 4D is a partial cross-sectional view of the processing module of FIG. 2A, showing an alternate configuration of the substrate support illustrated in FIG. 4C lifted into a process position to form a sealed substrate process volume therewith, according to one or more embodiments.

FIG. 5A is a schematic plan view of a robot useful to move substrates between process stations in the processing module of FIG. 2A, according to one or more embodiments.

FIG. 5B is an isometric view of an implementation of the robot of FIG. 5A, according to one or more embodiments.

FIG. 5C is a plan view of an alternative robot configuration to that of FIGS. 5A and 5B, according to one or more embodiments.

FIG. 6 is a partial cross-sectional view of a process station of the processing module of FIG. 4B, according to one or more embodiments.

FIG. 7A is an isometric view of a processing module that includes a structural support assembly useful to maintain co-planarity of a processing surface of source assemblies and substrate support surfaces disposed within the processing module, according to one or more embodiments.

FIG. 7B is a close-up isometric view of the structural support assembly disposed on a chamber upper wall of the processing module illustrated in FIG. 7A, according to one or more embodiments

FIG. 8 is a side cross-sectional view of the processing module formed along the sectioning line 8-8 illustrated in FIG. 7A, according to one or more embodiments.

FIG. 9A is a plan view of an alternate configuration of a processing module to that of FIG. 2A, according to one or more embodiments.

FIG. 9B is a plan view of a lower body portion of the processing module of FIG. 9A showing the motion path of paddle robots therein, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the disclosure provided herein generally provide a substrate processing system that includes at least one processing module that includes a plurality of process stations coupled thereto and a substrate transferring device disposed within a transfer region of the processing module for transferring a plurality of substrates to two or more of the plurality of process stations. The methods and apparatuses disclosed herein are useful for performing vacuum processing on substrates wherein one or more substrates are transferred within the transfer region of processing module that is in direct communication with at least a portion of a processing region of a plurality of separately isolatable process stations during the process of transferring the one or more substrates. In some embodiments, a substrate is positioned and maintained on the same substrate support member during the process of transferring the substrate within the processing module and while the substrate is being processed in each of the plurality of process stations.

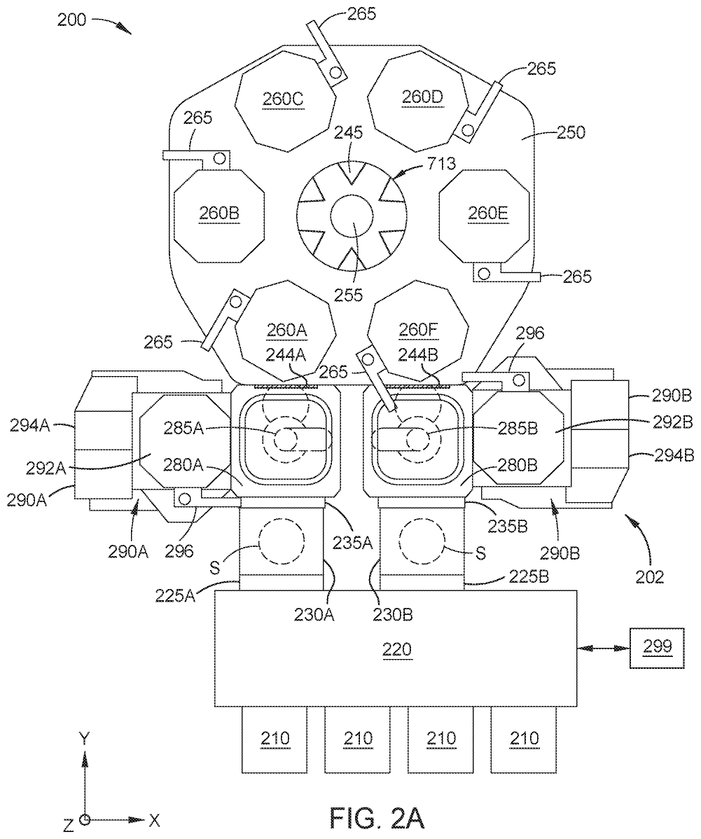

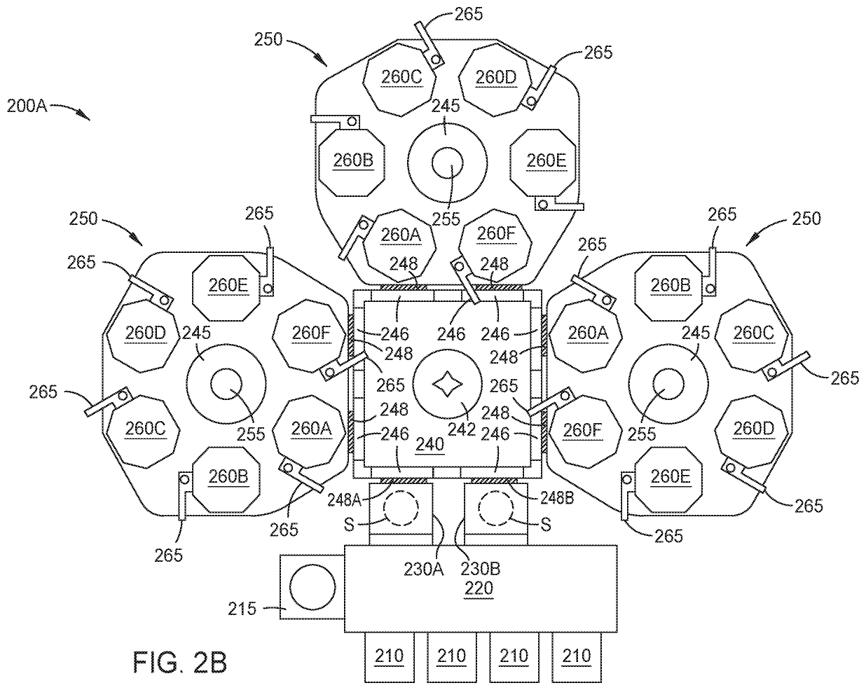

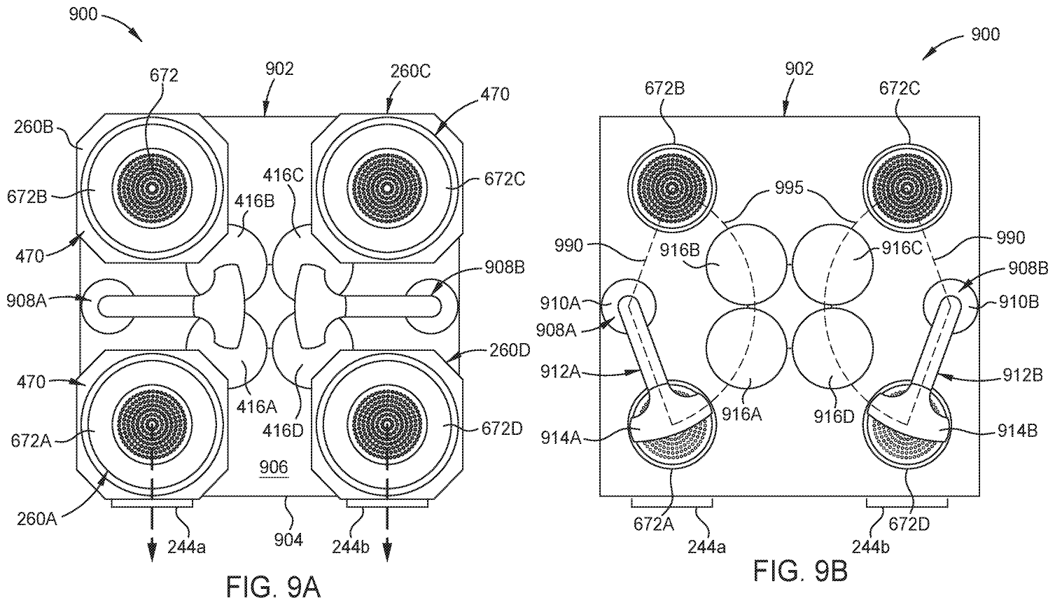

In one aspect of the disclosure provided herein, a substrate processing system as shown in FIG. 2A includes an atmospheric or ambient pressure substrate input and output handling station also known as a front end 220, a substrate processing module 250 having multiple process stations 260 positioned thereon, and at least one intermediary section 202. A substrate is transferred into the intermediary section 202 from the front end 220 or from the processing module 250, or transferred from the intermediary section 202 to the front end 220 or to the processing module 250. While the disclosure provided herein generally illustrates a processing module that include six process stations this configuration is not intended to be limiting as to the scope of the invention provided herein, since a processing module 250 might alternatively include two or more process stations 260, such as four or more process stations 260 (e.g., FIGS. 9A-9B), eight or more process stations 260, ten or more process stations 260, or even 12 or more process stations 260. However, in process sequences used to form next generation devices, which include multilayer film stacks like On chip Inductor, optical film stacks, hard mask, patterning and memory applications, it is believed that, due to the number of layers that are to be formed and the similar processing times used to form each of the layers, a six or a twelve process station containing the processing module 250 configuration will improve substrate throughput, system footprint, and CoO over more conventional designs known in the art.

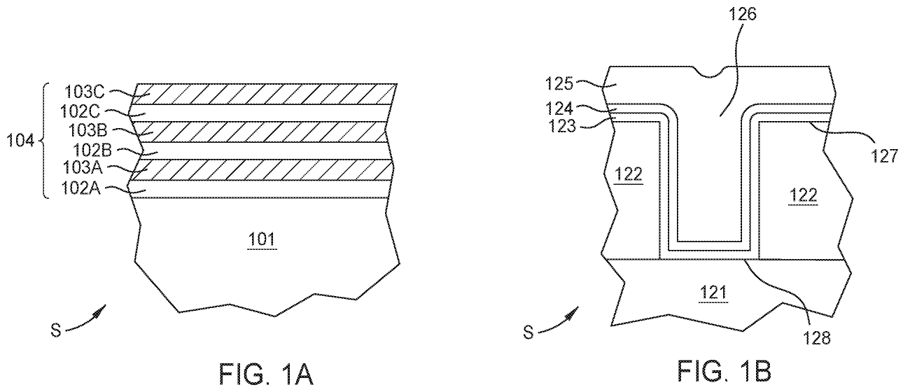

A processing system, such as processing system 200 of FIGS. 2A and 2B, is used to form one or more thin films on the surface of a substrate S and/or, on a layer previously formed or processed on the substrate S. FIG. 1A shows a portion 101 of a substrate S having a plurality of thin film layers 102 and 103 formed thereon, and FIG. 1B shows a plurality of film layers extending over a previously formed layer 122 layer, formed on a portion 121 of a substrate S.

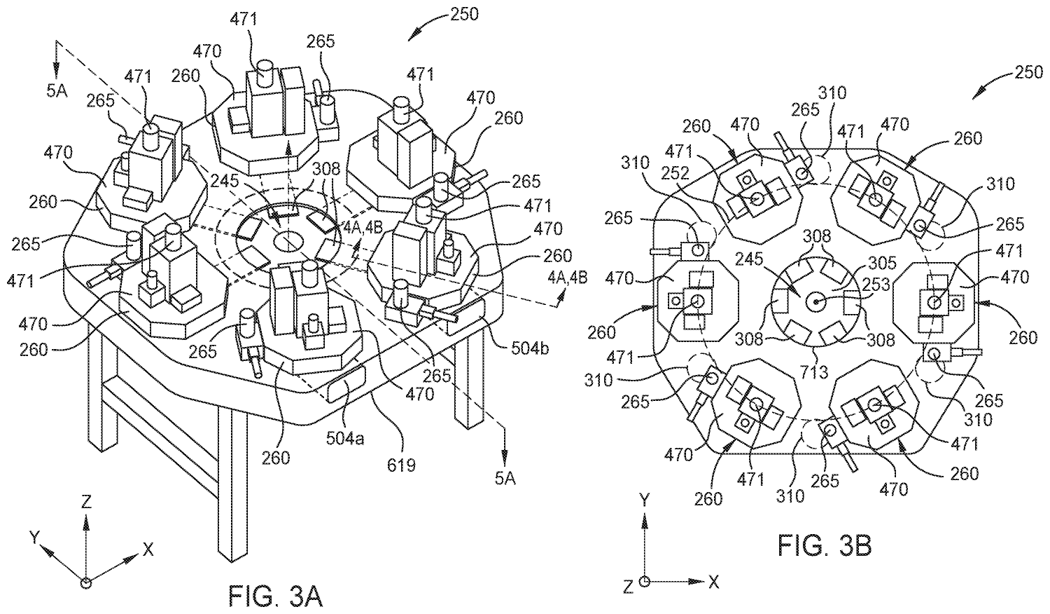

In FIG. 1A, a plurality of film layers 104 are shown sequentially layered on the portion 101 of the substrate S, or on a layer previously formed thereon. For example, using the processing system of FIG. 2A, wherein six process stations 260A-260F are accessible within the substrate processing module 250, a substrate may be sequentially moved along the circumference of an imaginary circle 252 (FIG. 3B) which intersects a central location of each of the process stations 260, such that a plurality of a first film type layer 102 and a plurality of a second film type layer 103 can be sequentially deposited thereon. Each process station 260A-260F can be independently or similarly configured to enable a deposition process, for example a PVD, CVD, ALD (atomic layer deposition) or other type of deposition process, or an etching process. For example, metal layers 102A-102C may deposited on a substrate and be composed of a metal, and reactive metal layers 103A-1030 may be deposited on a substrate and be composed of a reactive metal (e.g., metal nitride), wherein the metal in the reactive metal layers 103A-1030 is the same metal as the metal in the metal layers 102A-102C. In this example, during a substrate processing sequence performed in the processing module 250, the process stations 260B, 260D and 260F are used to form reactive metal layers 103A-103C (e.g., TaN, TiN, AIN, or SiN layers) on the exposed surface of the substrate by use of a reactive PVD deposition process, and the process stations 260A, 260C and 260E are used to form pure metal layers 102A-102C (e.g., Ta, Ti, Al, Co, Si layers) by use of non-reactive PVD deposition process, such that the process sequence allows a metal layer followed by a reactive metal layer to be formed. By sequentially moving and sequentially processing the substrate in all of process stations 260A-260F, a pure metal/reactive metal/pure metal/reactive metal/pure metal/reactive metal multi-layer film stack can be formed. Alternatively, the base materials of the thin film layers 102 and 103 may be different materials, in which case a sputtering target of a first material type is sputtered in process stations 260A, 260C and 260E, and a target of a second type is sputtered in process stations 260B, 260D and 260F to form alternating layers of a first material type and a second material type. Here, for example, alternating layers of a metal layers 102A-102C and a dielectric layer 103A-1030 or of a metal layer 102A-102C and a semiconductor layer 103A-1030 can be formed, for example alternating layers of molybdenum and silicon. Likewise a multi-layer film of the same material may be formed wherein all of layers 102A-102C and 103A-103C are the same material, and the substrate is sequentially moved to each process station to have the same material deposited thereon in each process station 260. The choice of the sputter target material, processing parameters (e.g., processing pressure) and the inert or reactive nature of the gas used to form the plasma in a process station 260, are user selectable such to allow the user or operator of the processing system 200 the flexibility to control the materials and material properties of any film within a film stack formed thereon. It has been found that substrate processing sequences that are used to form a repeating stacked layer configuration, as shown in FIG. 1A, wherein the stacked layer deposition processes (e.g., processes for forming thin film layers 102 and 103) have similar chamber processing times, a significant throughput increase and improved CoO has been observed when using the one or more system configurations and methods disclosed herein. In one example, it has been found that substrate processing sequences that include stacked layer deposition processes that have processing times less than 90 seconds, such as between 5 seconds and 90 seconds, in combination with the addition of lower substrate transferring overhead times achieved using the system architecture described herein, has a significant advantage over current conventional processing system designs.

A substrate loaded into the processing module 250 need not be processed at each process station 260A-260F. For example, each of the process stations 260A-260F can employ the same sputter target material, a number of substrates equal to the number of process stations 260 are loaded into the processing module 250, and each substrate is processed in a different one of the process stations 260 for deposition of a same material film layer thereon. Thereafter all of these substrates are removed from the processing module 250, and an equal number of substrates are loaded again into the processing module 250, and the processing of each of these substrates by a different single one of the process stations is performed. Alternatively, different processes are performed in each adjacent process station arrayed along the circumference of the imaginary circle. For example a first deposition process to deposit a first type of film layer is performed in process stations 260A, 260C and 260E, and a second deposition process to deposit a second type of film layer is performed in process stations 260A, 260C and 260E. However, in this case, an individual substrate is exposed to only two process stations 260, for example a first substrate is exposed to only process stations 260A and 260B, a second substrate is exposed to only process stations 260C and 260D, and a third substrate is exposed to only process stations 260E and 260F. Then the substrates are removed. Likewise, each substrate process in the system can be processed in up to all process stations 260, and the process performed at each process station 260 can be the same or different from one or all of the remaining process stations 260.

Referring to FIG. 1B, a feature 126 extending inwardly of a dielectric layer 122 is shown. Here, the feature, such as a trench, a contact, or a via, has been formed into and through the dielectric layer 122 such as by pattern etching the dielectric layer 122 through a patterned mask (not shown). In FIG. 1B the feature 126 is a conductive via disposed in a via opening 128, wherein the via opening 128 extends down to an underlying conductive layer 121 previously formed on a substrate (not shown), for example a copper layer used in an integrated circuit device. To form the feature 126 in the via opening 128, a barrier layer 123 is first formed over the upper surface or field 127 of the dielectric layer 122, over the sidewall(s) of the via opening 128, and over the portion of the conductive layer 121 exposed at the base of the via opening 128. The barrier layer 123 may include a single material layer, or two or more different materials in a stack. For example, a bi-layer of a tantalum film layer followed by a tantalum nitride film layer, may be employed, and each sub layer of the bi-layer may be formed in one or more of the process stations 260A-260F of FIG. 2A. Then, a seed layer 124, for example a thin layer of copper, is formed over the previously deposited barrier layer 123. The seed layer 124 is used to promote plating of a copper layer 125 thereover in a copper plating tool separate from the processing system 200. Here, using the processing system 200, a tantalum bilayer can be sputtered from a tantalum target onto the same substrate at process stations 260A, 260B, then a tantalum nitride layer can be deposited on the tantalum layer by reactive sputtering of a tantalum target in an inert gas-nitrogen gas plasma to form a tantalum nitride layer thereon in process stations 260C, 260D, and a copper seed layer is formed over the tantalum nitride layer by sputtering a copper target in an inert gas plasma at process stations 260E, 260F. Alternatively, the tantalum layer could be deposited in on a substrate in process station 260A or 260D, the tantalum nitride layer on a substrate in process station 260B or 260E, and the copper seed layer deposited on the substrate in process station 260C or 260F. In this configuration, a first substrate is sequentially processed in process stations 260A-260C, and a second substrate is sequentially processed in process stations 260D-260F. As will be discussed further below, it is believed that substrate processing sequences that are used to deposit materials in a set grouping of processing sequences, as shown in FIG. 1B, will achieve a significant throughput increase when using one or more of the system designs and methods disclosed herein.

### Processing System Configuration Examples

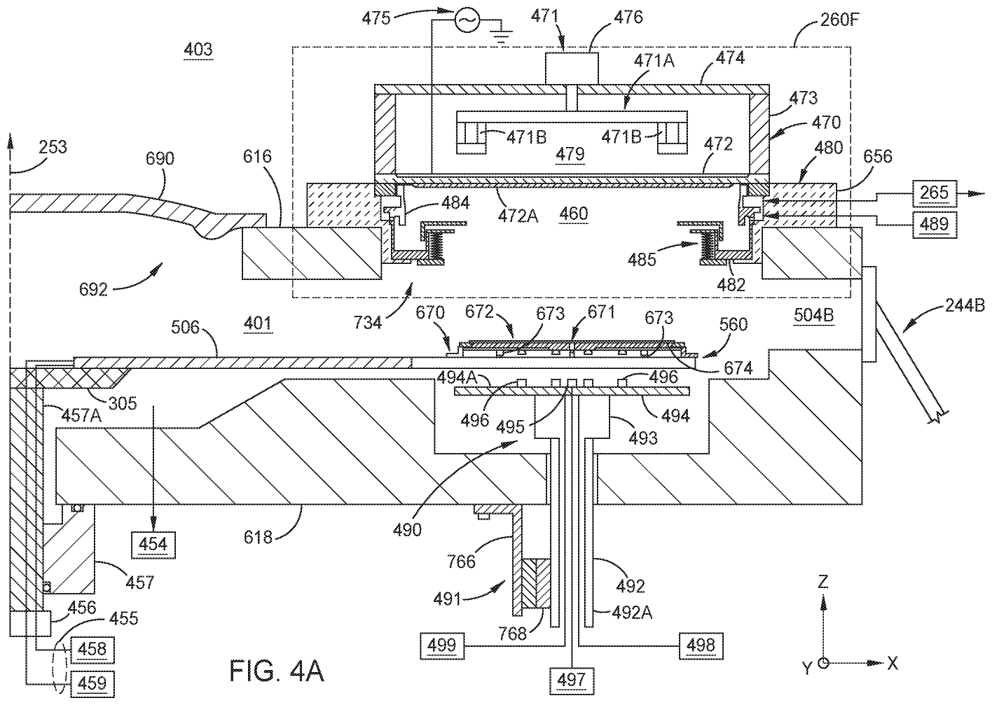

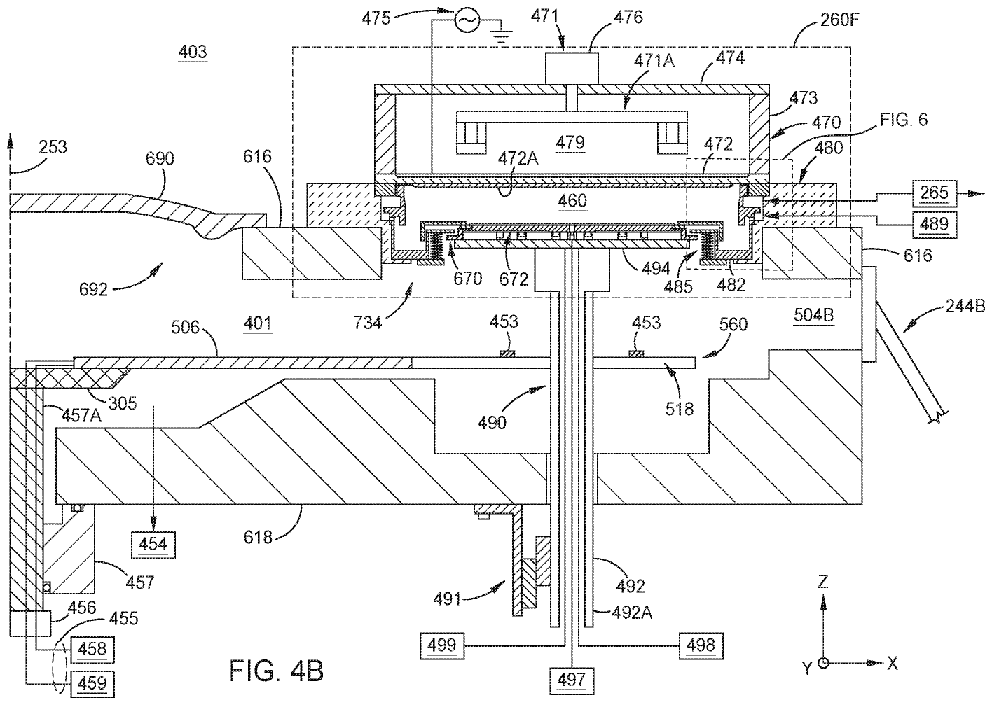

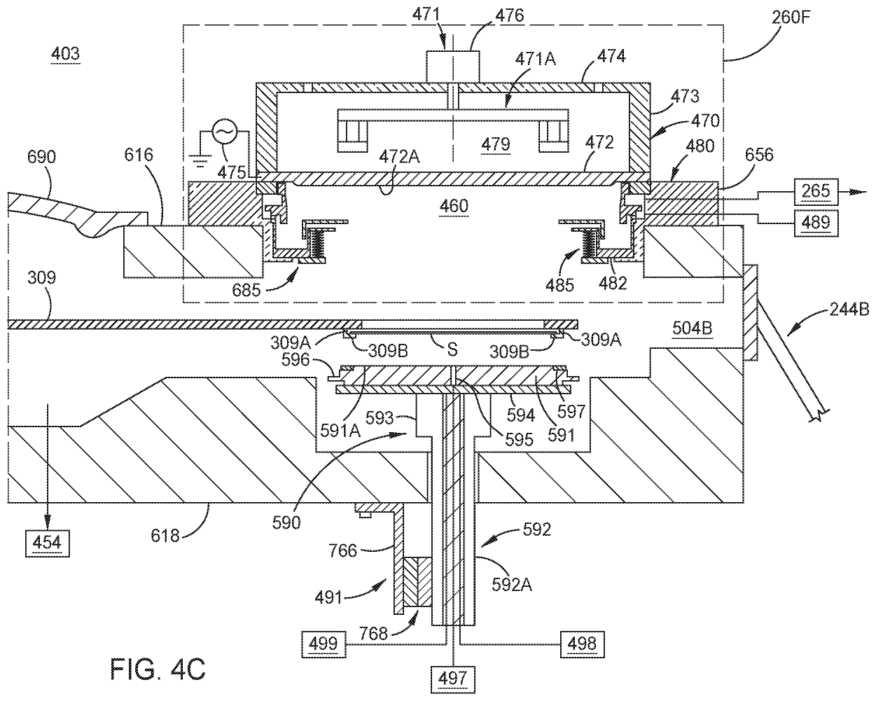

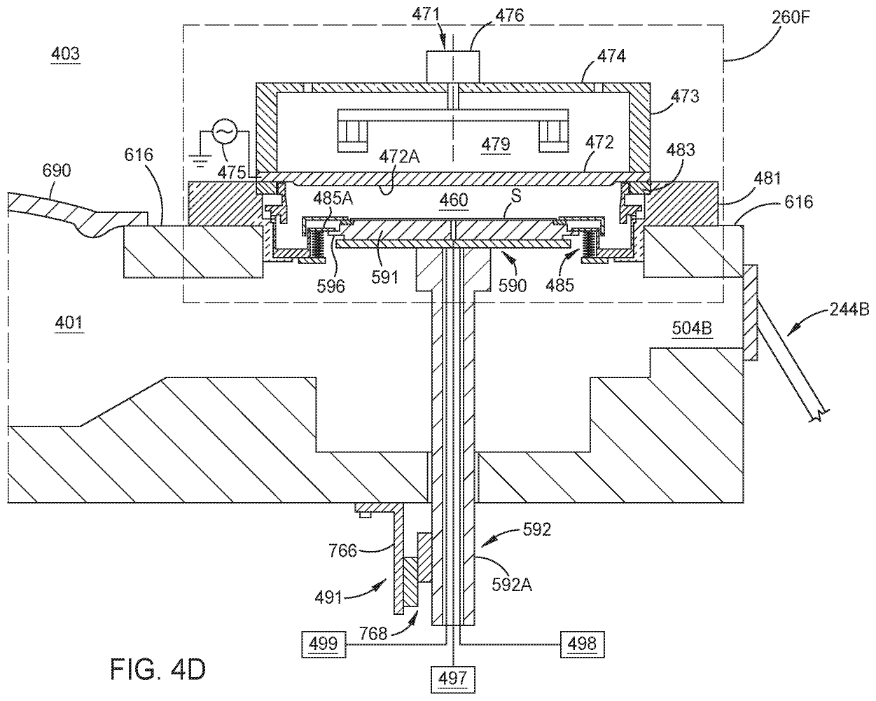

Referring again to FIG. 2A, processing system 200 generally includes the processing module 250, the intermediary section 202, which is coupled between the processing module 250 and the front end 220, and a system controller 299. As shown in FIG. 2A, the intermediary section 202 includes a pair of load lock chambers 230A, 230B and a pair of intermediate robot chambers 280A, 280B. Each of the load lock chambers 230A, 230B is separately connected through a respective first valve 225A, 225B, at one side thereof to the front end 220, and through a respective second valve 235A, 235B, to one of the intermediate robot chambers 280A, 280B, respectively. During operation a front end robot (not shown) in the front end 220 moves a substrate therefrom into a loadlock chamber 230A or 230B, or removes a substrate from a loadlock chamber 230A, 230B. Then an intermediary robot 285A, 285B in one of the associated intermediate robot chambers 280A, 280B connected to an associated one of the loadlock chambers 230A, 230B moves a substrate from the loadlock chamber 230A or loadlock chamber 230B and into the corresponding intermediate robot chamber 280A, 280B. In one aspect, the intermediary station 202 also includes a preclean/degas chamber 292 connected to an intermediate robot chamber 280, for example a preclean/degas chamber 292A connected to intermediate robot chamber 280A and a preclean/degas chamber 292B connected to intermediate robot chamber 280B. A substrate loaded into one of the loadlock chambers 230A, 230B from the front end 220 is moved, by the associated intermediary robot 285A or 285B, from the loadlock chamber 230A or 230B and into the preclean/degas chamber 292A or 292B. In the preclean/degas chambers 292A, 292B, the substrate is heated to volatilize any adsorbed moisture or other volatilizable materials therefrom, and is subjected to a plasma etch process whereby residual contaminant materials thereon are removed. Thereafter, the substrate is moved by the appropriate associated intermediary robot 285A or 285B back into the corresponding intermediate robot chamber 280A or 280B and thence onto a substrate support 672 (FIG. 4A, B) at a process station 260 in the substrate processing module 250, here process station 260A or 260F. In some embodiments, as illustrated in FIGS. 4A and 4B, once the substrate S is placed on the substrate support 672, it remains thereon until all processing thereof in the processing module 250 is completed.

Here, each of the loadlock chamber 230A and the loadlock chamber 230B is connected to a vacuum pump (not shown), for example a roughing pump, the output of which is connected to an exhaust duct (not shown), to reduce the pressure within the loadlock chamber 230A, 230B to a sub-atmospheric pressure on the order of about 10⁻³ torr. Each loadlock chamber 230A or 230B may be connected to a vacuum pump dedicated thereto, or a vacuum pump shared with one or more components within the processing system 200, or to a house exhaust other than a vacuum pump to reduce the pressure therein. In each case, a valve (not shown) can be provided on the loadlock chamber 230A, 230B exhaust to the pump or house exhaust to isolate, or substantially isolate, the pumping outlet of the loadlock chamber 230A, 230B connected to the vacuum pump or house exhaust from the interior volume of the loadlock chamber 230A, 230B when the first valve 225A or 225B respectively is open and the interior of the loadlock chamber 230A, 230B is exposed to atmospheric or ambient pressure conditions.

After the substrate has been processed, for example, in the, preclean/degas chamber 292B, the intermediate robot 285B removes the substrate from the preclean/degas chamber 292B. A process chamber valve 244B, which is disposed between the intermediate robot chamber 280B and the processing module 250, is opened to expose an opening 504B (FIGS. 3A and 4A) formed in a wall of the processing module 250, and the intermediate robot 285B moves the substrate through the opening 504B to a process station 260F of the processing module 250 where it is received for processing within one or more of the process stations of the processing module 250. In the same manner, a substrate can be moved from the front end 220 through the loadlock chamber 230A, to the preclean/degas chamber 292A, and then to the processing module 250 through a process chamber valve 244A (FIG. 2A) and an opening 504A in the processing module 250 wall to be received at process station 260A. Alternatively, the process chamber valves 244A, 244B may be eliminated, and intermediate robot chambers 280A, 280B be in direct uninterrupted fluid communication with the interior of the processing module 250

Each of the loadlock chambers 230A, 230B and intermediate robot chambers 280A, 280B are configured to pass substrates from the front end 220 into the processing module 250, as well as from the processing module 250 and into the front end 220. Thus, with respect to the first intermediate robot chamber 280A, to remove a substrate positioned at process station 260A of the processing module 250, the process chamber valve 244A is opened, and the intermediate robot 285A removes the substrate from the process station 260A and moves it, through an open second valve 235A connected between the intermediate robot chamber 280A and the loadlock chamber 230A, to place the substrate in the loadlock chamber 230A. The end effector of the intermediate robot 285A on which the substrate was moved is retracted from the load lock chamber 230A, the second valve 235A thereof is closed, and the interior volume of the loadlock chamber 230A is optionally isolated from the vacuum pump connected thereto. Then the first valve 225A connected to the loadlock chamber 230A is opened, and the front end 220 robot picks up the substrate in the loadlock chamber 230A and moves it to a storage location, such as a cassette or FOUP 210, located within or connected to a sidewall of, the front end 220. In a similar fashion, using the intermediate robot chamber 280B, the intermediary robot 285B, the loadlock chamber 230B and associated valves 235B and 225B thereof, a substrate can be moved from the process station 260F location to the front end 220. During the movement of a substrate from the processing module 250 to the front end 220, a different substrate may be located within the preclean/degas chamber 292A, 292B connected to the intermediate robot chamber 280A, 280B through which the substrate being moved to the front end 220 passes. Because each preclean/degas chamber 292A, 292B is isolated from the intermediate robot chamber 280A, 280B to which it is attached by a valve, passage of a different substrate can be undertaken from the processing module 250 to the front end 220 without interfering with the processing of a substrate in the respective preclean/degas chambers 292A, 292B.

The system controller 299 controls activities and operating parameters of the automated components found in the processing system 200. In general, the bulk of the movement of a substrate through the processing system is performed using the various automated devices disclosed herein by use of commands sent by the system controller 299. The system controller 299 is a general use computer that is used to control one or more components found in the processing system 200. The system controller 299 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, and/or positioning of a substrate along with the various process recipe tasks and various processing module process recipe steps being performed.

Referring to FIG. 2B, an alternate construct of a processing system 200A is shown, wherein a transfer chamber 240 is interposed between the loadlock chambers 230A, 230B and one or more processing modules 250. While not intended to be limiting as to the scope of the disclosure herein, the processing system 200A shown in FIG. 2B does not include separate intermediate robot chambers 280A, 280B or preclean/degas chambers 292A, 292B. Here, by the use of an intermediate transfer chamber 240, having a transfer chamber robot 242 located therein, multiple processing modules 250 are connectable to a single front end 220. Here, transfer chamber 240 is generally rectangular in plan view, and includes four generally planar upright walls 246, attached to three of which are processing modules 250 and to a fourth of which is connected the loadlock chambers 230A, 230B through the second valves 235A, 235B, and openings 244A, 244B, respectively. Here, after the front end robot places a substrate into one of the loadlock chambers 230A, 230B while the second valve 235A, 235B respectively thereof is closed, the first valve 225A, 225B thereof, respectively, is then closed, the second valve 235A, 235B thereof is opened, and the transfer chamber robot 242 (shown schematically in FIG. 2B) takes the substrate from the loadlock chamber 230A or 230B and places it into one of the first process stations 260A of a processing module 250 through a processing system valve 248 which is selectively openable to move substrates into and out of the processing module at station 260A, and closeable to isolate the interior volume of the transfer chamber 240 from the interior volume (e.g., transfer region 401) of the processing module 250.

As there is no intermediate robot chamber 280A, 280B and/or preclean/degas chamber 292A, 292B within the processing system 200A, as in the processing system 200 of FIG. 2A, precleaning of substrates occurs within the one or more of the processing modules 250, such as at a process station 260A to allow the precleaning process to be performed before a film layer is deposited thereon.

### Processing Module Configuration(s)

Referring to FIGS. 2A, 3A-3B, 4A-4B, 5 and 8, in which further details of the components within and the interior regions of a processing module 250 are shown. As shown in FIGS. 4A and 4B, a removable central cover 690 extends over a central opening 713 (FIGS. 2A, 3B, and 8) in an upper wall 616 of the processing module 250. The central cover 690 is removable to allow access to the interior, transfer region 401, of the processing module 250 to service a central transfer robot 245 thereof. At least one, and in the case of the processing module 250 of FIG. 3A and 4A-4B, two substrate transfer openings 504A, 504B extend inwardly of the outer surface of a circumferential wall 619 and into the transfer region 401 of the processing module 250. The transfer openings 504A, 504B allow the intermediary robot 285A, 285B, or the central transfer robot 245, to transfer a substrate positioned external to the processing module 250 to a position on a substrate support 672 that is positioned on a support arm 308 of the central transfer robot 245. Alternately, transfer openings 504A, 504B allow the intermediary robot 285A, 285B, or the central transfer robot 245, to remove a substrate from a substrate support 672 that is positioned on the support arm 308 of the central transfer robot 245.

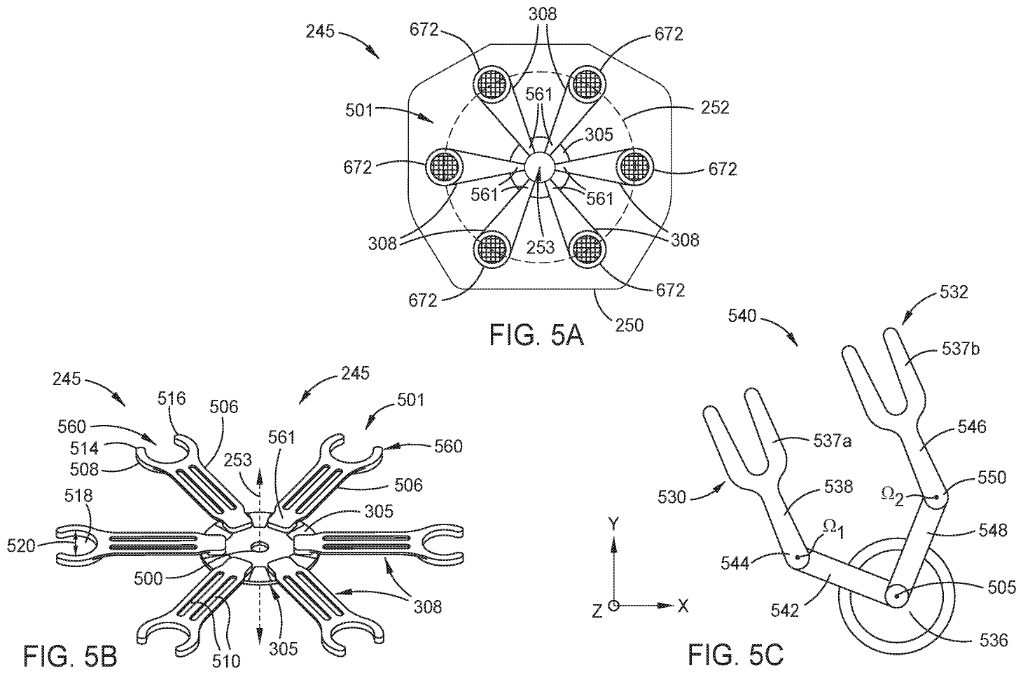

In FIGS. 4A and 4B, process station 260F of FIGS. 2A and 3A-3B is shown, wherein opening 504B opens into the processing module 250 at process station 260F. In this example, the location of the opening 504A corresponds to a location that is adjacent to the process station 260A. The processing module 250 is configured to include the central transfer robot 245 (FIGS. 3A, 3B), from which a plurality of support arms 308 radially extend. In some embodiments, as shown in FIG. 5A, the number of support arms 308 is equal to the number of process stations 260 of the processing module 250. However, the number of support arms 308 of central transfer robot 245 can be less than or greater than the number of process stations 260 of the processing module 250. In one embodiment, the number of support arms 308 is greater than the number of process stations 260 to allow more substrates to be transferred through the transferring region at one time and/or allow some of the support arms 308 to support additional hardware components, such as a pasting disk (not shown) that is used to perform a PVD pasting operation to remove contamination from a surface of a PVD target. A PVD pasting operation is typically performed in a process station 260 between two substrate PVD deposition processes performed in the same substrate process station 260.

The process stations 260 are arrayed, and are equally and circumferentially spaced from one another, along an imaginary circle 252 (FIG. 3B) centered on central axis 253 (i.e., parallel to the Z-direction), such that the center the imaginary circle 252 is coincident with the central axis 253. For example, where the process station 260F is a PVD type of process station 260, the center of the PVD target overlies a portion of the imaginary circle 252, and the centers of the targets of the remaining process stations 260A-260E are equally circumferentially spaced from one another along the imaginary circle 252. The circumferential spacing measured along the imaginary circle 252 between the centers of two adjacent the process stations 260 can be between about 700 mm and about 1000 mm, such as between 800 mm and 900 mm. In some embodiments, the circumferential spacing measured along the imaginary circle 252 between the centers of two adjacent the process stations 260 can be greater than about 0.5 of the diameter of a substrate that is being processed within the processing system and less than about 3 diameters of a substrate that is being processed within the processing system, such between about 1 and about 2 substrate diameters (e.g., system may be configured to process 150 mm, 200 mm, 300 mm, 450 mm or even greater than 450 mm diameter substrates).

### Central Transfer Robot

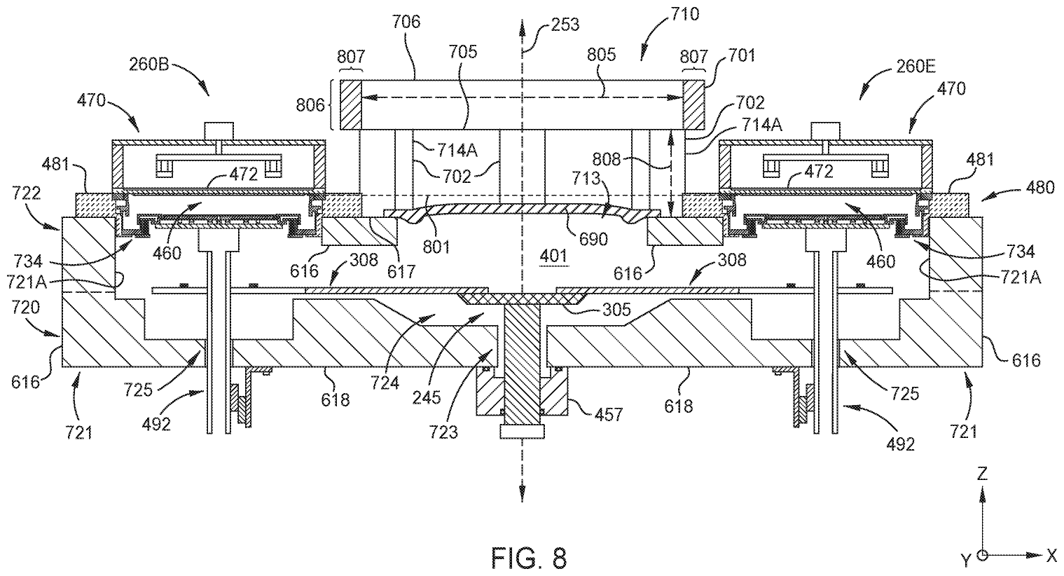

Referring to FIGS. 3A-3B, 4A-4B and 5A-5B, the central transfer robot 245 is a carousel type robot assembly 501 that includes a central support 305, to which the proximal end 561 of the support arms 308 are affixed, such as by threaded fasteners (not shown). The central support 305 is rotated by a carousel motor 457 (FIGS. 4A-4B and 8) positioned below the processing module 250, and may include a stepper motor or a servo motor that is coupled to the lower wall 618 (FIG. 4A). The carousel motor 457 can include a drive shaft 457A that is coupled to the central support 305 and is coincident with the central axis 253 so as to cause the central support 305 and each of the support arms 308 to rotate through an arc centered about the central axis 253 as the drive shaft of the carousel motor 457 rotates. The uppermost surface of a revolved volume through which the support arms 308 and substrate supports 672 pass as they are rotated by the carousel motor 457 is generally referred to herein as the transfer plane, which is parallel to the X-Y plane in FIG. 4A. The central support 305 and each of the support arms 308 are positioned within the transfer region 401 that is separately evacuated by a vacuum pump 454, which can be a turbopump, cryopump, roughing pump or other useful device that is able to maintain a desired pressure within the transfer region 401 of the processing module 250. The central support 305 is generally positioned over a central opening 723 (FIG. 8) formed in the lower wall 618 of a lower monolith 720. As will be discussed further below, the transfer region 401 and processing region 460 of a process station 260 are separately isolatable so that processes being performed in a process station 260 can be controlled and performed at a different vacuum pressure than the transfer region 401 and use various different processing gases without the concern of contaminating the transfer region 401 or other adjacently positioned process stations 260.

In some embodiments, support arms 308 are configured to support a substrate support 672 that is configured to support a substrate that is to be processed in a processing region of a process station 260. Substrates that are positioned on the substrate supports 672, which are positioned on the support arms 308, are positioned so that the center of the substrate is positioned over a portion of the imaginary circle 252, within tolerance limits of the placement of the substrate thereon. Likewise, the region of each of the support arms 308 on which a substrate support is placed, or supporting portion 560 (FIG. 4A), is also aligned with the imaginary circle 252 (FIG. 3B and 5A) to allow the center of the supporting portion 560 to traverse the imaginary circle 252 as the supporting portion 560 orbits around the central axis 253 when the central support 305 is rotated about the central axis 253.

Referring to FIG. 5B, one configuration of the central transfer robot useful for transferring substrate supports 672 between the process stations 260A-260F of FIGS. 2A and 2B is shown. Here, central support 305 includes a centrally located through opening 500, centered around the central axis 253 and into which the drive shaft 457A of the carousel motor 457 (FIG. 4A) positioned below the processing module 250, is connected to cause rotation of the central support 305 about central axis 253. Each support arm 308 includes an extension arm portion 506 that is positioned between the supporting portion 560 and the proximal end 561. The extension arm portion 506 has at least one, and here two, weight reduction and thermal heat conduction reducing cutout regions 510 that extend generally parallel to either side of a radius extending from the central axis 253. In some configurations, the extension arm portion 506 terminates at a c-shaped end region 508, as seen in a plan view, and forms part of the supporting portion 560. In some configurations, the c-shaped end region 508 includes opposing ends 514, 516 that are spaced apart a distance that is smaller than a diameter 520 of a through opening 518 that the c-shaped end region 508 partially surrounds. A perimeter flange 670 (FIG. 4A) of the substrate support 672, which is generally circular in layout has an inner and an outer diameter, and is configured to rest on the top on the supporting portion 560 during movement of the substrate support 672 between process stations 260, and at the process station 260 prior to the substrate support 672 being lifted therefrom.

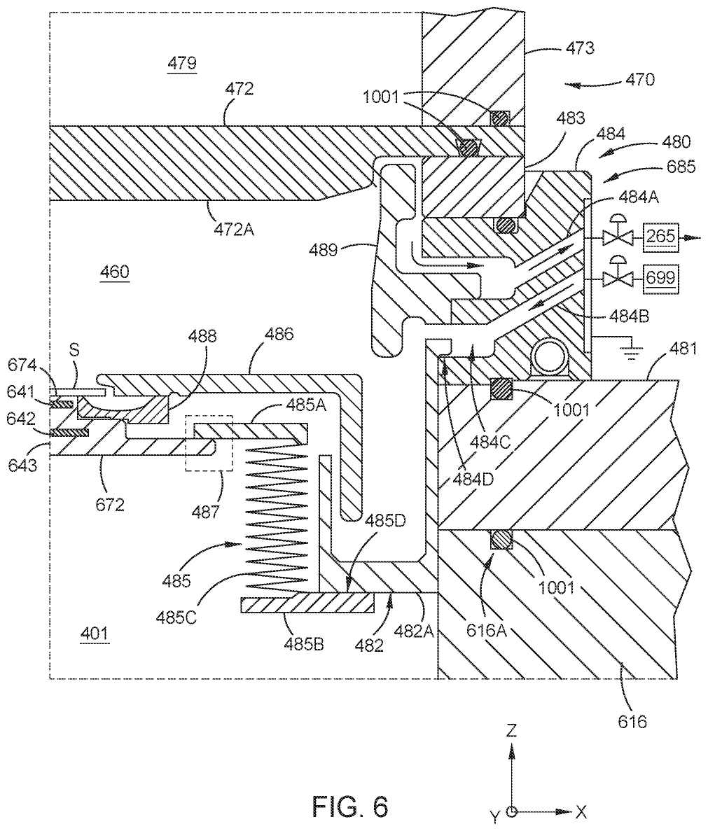

Referring to FIGS. 4A-4B, in some embodiments, the support arms 308 include a plurality of electrical contacts 453 (FIG. 4B) that are disposed on an upper surface of the support arm 308 and within the supporting portion 560. The electrical contacts 453 are used to provide electrical power to one or more electrical elements formed within a body 643 (FIG. 6) of the substrate support 672 while the substrate support 672 is supported on the support arm 308. The one or more electrical elements formed within the substrate support 672 can include resistive heating elements 642 (FIG. 6) that are coupled to two or more electrical contacts 673 (FIG. 4A) formed on a lower surface of the substrate support 672, and/or one or more chucking electrodes 641 (FIG. 6) that are separately coupled to two or more additional electrical contacts 673 formed on a lower surface of the substrate support 672. As schematically illustrated in FIGS. 4A-4B, the electrical contacts 453 are electrically coupled to one or more power sources, such as a DC chucking power supply 458 and/or a heater power supply 459 by use of a slip ring 456 that is adapted to allow electrical connections to be made to the electrical contacts 453 while the support arms 308 are rotated by the carousel motor 457. Multiple conductors or wires 455 are used to connect the one or more power sources to the electrical contacts 453. The conductors or wires 455 are routed through the motor shaft 457A, central support 305, and support arms 308, which is positioned within the transfer region 401 of the processing module 250. For example, three wires that are coupled to the power supply 458 and two wires that are coupled to the power supply 459 are provided through each support arm 308 so that they can each be separately connected to an electrical contact 453. Therefore, when the substrate support 672 is positioned on the supporting portion 560, the electrical contacts 673 of the substrate support 672 are electrically coupled to the electrical contacts 453 of the support arms 308 so that a substrate can remain chucked to the substrate support 672 and a desired temperature can be maintained while the substrate S and substrate support 672 are being transferred within the transfer region 401. The ability to allow the substrate S to be chucked and heated during a transferring process allows greater rotational speeds to be achieved by the carousel motor 457 during a transfer process without the concern of losing the substrate, and allows the temperature of the substrate to be consistently maintained between processes performed in each process station 260.

FIG. 5C is a plan view of the central transfer robot 245 that includes an alternative robot construct that is a dual arm robot 540 that includes two end effectors 530, 532. A central transfer robot 245 that includes a dual arm robot 540 can be useful in cases where a substrate processing sequence performed in a processing module 250 does not include or require the substrate to be sequential transferred along a path that extends along the imaginary circle 252 in either direction. In this processing module 250 configuration, the substrate supports 672 need not be moveable in a lateral plane (i.e., X-Y plane) such that each substrate support 672 is maintained in one position in the X-Y plane beneath a process station 260, and during processing the substrates are transferred between the laterally fixed substrate supports 672 by the dual arm robot 540.

In some embodiments, the two end effectors 530, 532 of the dual arm robot 540 are independently operable and extend from, and swing arcuately about a central axis 505 which extends in the Z-direction (e.g., perpendicular to the plane of FIG. 5C) and is typically coincident with the central axis 253 of the processing module 250. Each end effector 530, 532 is operatively coupled to a central hub 536, composed of an upper rotatable hub and a lower rotatable hub (not shown) that are each independently rotatable about central axis 505. End effector 530 includes a first fork 537a and a first arm 538. A first hub arm 542 is coupled to the central hub 536 at a first end thereof and to the first arm 538 at the end thereof distal to the end effector 536a at a first wrist connection 544, whereby the first arm is pivotable about a first wrist axis Ω1 to allow the first end effector 530 to rotate about the first wrist axis Likewise, the first wrist connection 544, and thus the first wrist axis can orbit about the central axis 505, by virtue of the arcuate movement of the first hub arm about the central axis 505. End effector 532 includes a second fork 537b and a second arm 546. A second hub arm 548 is coupled to the upper rotatable hub at a first end thereof and to the second arm 546 at the end thereof distal to the second end effector 532 at a second wrist connection 550, whereby second arm 546 is pivotable about a second wrist axis Ω2 to allow the second end effector 532 to rotate about the second wrist axis 02. Likewise, the second wrist connection 550, and thus the second wrist axis Ω2, can orbit about the central axis 505, by virtue of the arcuate movement of the second hub arm 548 about the central axis 505. Additionally, as the first and second end effectors 530, 532 are operatively connected to the central hub 536 through an upper rotatable hub and a lower rotatable hub respectively, the forks 537a, 537b of the end effectors 530, 532 may overlie one another in the vertical direction, for example to allow one of the forks 537a or 537b to receive and retract a substrate from a substrate support 672 while the other of the forks 537a or 537b is moving a different substrate inwardly of the processing module 250 to place a substrate on the substrate support 672 once the first substrate has been removed therefrom.

Each of the forks 537a, 537b of the first and second end effectors 530, 532 can extend a maximum distance from the central axis 505 when the arms (first arm 538 and first hub arm 542, or second arm 546 and second hub arm 548) thereof are co-aligned, i.e., when they together form a straight line path. In this orientation of the arms, one of the first and second fork 537a or 537b is at the load or unload position to receive or leave a substrate with respect to a substrate support 672. From this position, by virtue of arcuate movement of an upper or lower hub about central axis 505 and one of the first or the second arms 538, 546 about the corresponding first wrist axis Ω1 or second wrist axis Ω2, the corresponding fork 537a or 537b is retracted toward the central hub 536. By locating the dual arm robot 540 in processing module 250, and locating central axis 505 at the location of the central axis 253, the forks 537a, 537b are operable to access any substrate support 672 at any of the process stations 260A-F, and independently of one another. Thus, employing a robot of the structure of dual arm robot 540, a substrate can be moved from any of the process stations 260A-F to any other of the process stations 260A-260F without passing through any intermediate process station 260A-260F along the imaginary circle 252.

### Process Station Configurations

FIGS. 4A-4B and 6, include cross-sectional views of portions of the process station 260F and processing module 250, and are intended to generally illustrate various components and attributes of a process station that can be positioned within a processing module 250. While the configuration of the process station 260F illustrated in these figures is adapted to perform a PVD deposition process, this process station configuration is not intended to be limiting as to the scope of the disclosure provided herein, since, as noted above, one or more of the process stations 260 within a processing module 250 can be adapted to perform a CVD, PECVD, ALD, PEALD, etch, thermal process (e.g., RTP, anneal, cool down, thermal management control) and/or other useful semiconductor or flat display panel substrate processing step. In some embodiments, the processing module 250 is configured to perform a PVD process in at least one processing station 260 and at least one other type of process, such as a CVD, PECVD, ALD, PEALD, etch, or thermal process, in at least one other processing station 260. However, it is believed that processing modules 250 that primarily include or only include process stations that are configured to perform PVD deposition processes are advantageous in a number of semiconductor device forming applications over other processing module configurations that utilize other deposition and etching processes due to a reduced chance of process cross-contamination (e.g., smaller chance of residual gas cross-contamination) and the higher deposition rates commonly achieved by PVD processes.

The process station 260 generally includes a source assembly 470, a process kit assembly 480 and a substrate support actuation assembly 490, which when used together enable a desired process to be performed within a processing region 460 of the process station 260. In various embodiments of the disclosure provided herein, the processing region 460 within each of the process stations 260 is configured to be separately isolatable from the transfer region 401 of the processing module 250, and thus substantially prevent electromagnetic energy, vapors, gases or other undesirable contaminants from adversely affecting substrates and processes being performed in adjacent process stations or within the transfer region 401. When isolated from the transfer region 401, during a substrate processing step performed within a process station 260, the processing region 460 is generally enclosed by one or more processing surfaces of the source assembly 470, one or more processing region components 685 within the process kit assembly 480, and the substrate support 672.

As discussed above and shown in FIG. 4A, the source assembly 470 of the process station 260F is configured to perform a PVD deposition process. In this configuration, the source assembly 470 includes a target 472, a magnetron assembly 471, source assembly walls 473, a lid 474 and a sputtering power supply 475. In this configuration, a processing surface 472A of the PVD target 472 generally defines at least a portion of the upper portion of the processing region 460. The magnetron assembly 471 includes a magnetron region 479 in which the magnetron 471A is rotated by use of a magnetron rotation motor 476 during processing. The target 472 and magnetron assembly 471 are typically cooled by the delivery of a cooling fluid (e.g., DI water) to the magnetron region 479 from a fluid recirculation device (not shown). The magnetron 471A includes a plurality of magnets 471B that are configured to generate magnetic fields that extend below the processing surface 472A of the target 472 to promote a sputtering process performed in the processing region 460 during a PVD deposition process.

Alternate configurations of the process stations 260, which are adapted to perform CVD, PECVD, ALD, PEALD, etch, or thermal processes, the source assembly 470 will generally include different hardware components. In one example, the source assembly 470 of a process station that is adapted to perform a CVD deposition process, a PECVD deposition process or an etch process will include a gas distribution plate, or showerhead, that is configured to deliver a precursor gas or etching gas into the processing region 460 and across a surface of a substrate disposed within the process station 260 during processing. Generally, a showerhead, or gas distribution plate, includes a metal, quartz or ceramic plate that has a plurality of holes (e.g., >100 holes) formed therein to restrict and thus allow an even distribution of a gas to flow from an upstream side of the showerhead to a downstream side of the showerhead, which is positioned adjacent to the processing region 460 of a processing station 260 during processing. The gas (e.g., precursor gas or etching gas) is delivered to the upstream side of the showerhead and through the showerhead by a precursor gas source (not shown) typically disposed outside of the processing system 200. In this configuration of the source assembly 470, the one or more processing surfaces that define at least a portion of the processing region 460 is the lower surface of the gas distribution plate, or showerhead (e.g., surfaces that contact the processing region). In this configuration, the magnetron assembly 471 and target are not used, and the sputtering power supply 475 can be replaced with a RF power supply that is configured to bias the gas distribution plate.

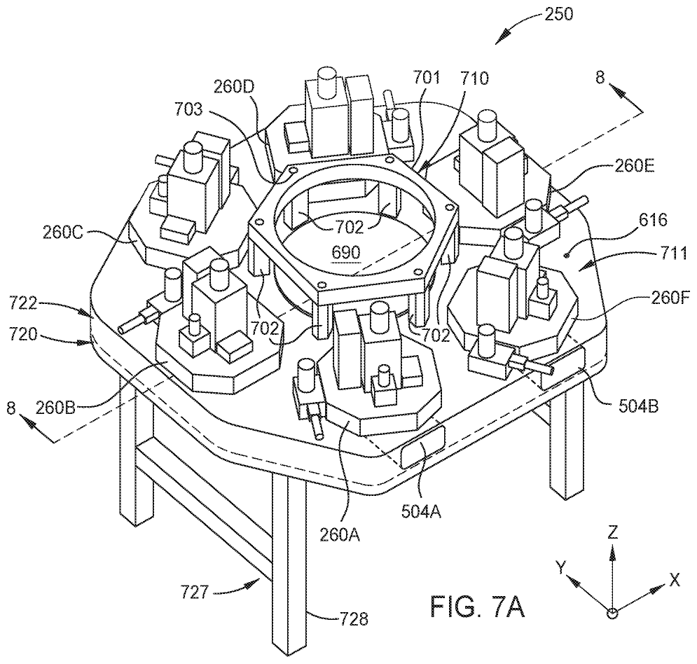

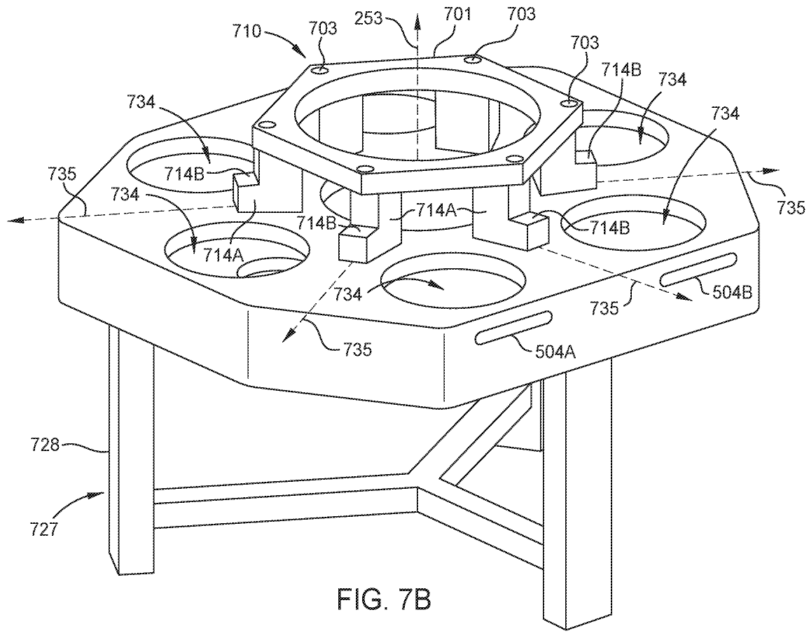

The substrate support actuation assembly 490 includes a pedestal lift assembly 491 and a pedestal assembly 492. The pedestal lift assembly 491 includes a lift actuator assembly 768 and a lift mounting assembly 766, which is coupled to the lower wall 618 of the processing module 250. The lift actuator assembly 768 may include a stepper or servo motor actuated lead screw assembly, linear motor assembly, pneumatic cylinder actuated assembly or other conventional mechanical linear actuation mechanism. During operation the lift actuator assembly 768 and lift mounting assembly 766 are configured to position the pedestal assembly 492 in a transfer position (FIG. 4A), which is positioned vertically (Z-direction) below the support arms 308 (i.e., transfer plane), and a processing position (FIG. 4B), which is vertically above the support arms 308 by use of one or more mechanical actuators (e.g., servo motor, stepper motor, linear motor) found within the lift actuator assembly 768. The lift actuator assembly 768 is coupled to the pedestal shaft 492A, which is supported by bearings (not shown) that are coupled to the lower wall 618 to guide the pedestal shaft 492A as it is translated by the lift actuator assembly 768. A bellows assembly (not shown) is used to form a seal between the outer diameter of the pedestal shaft 492A and a portion of the lower wall 618, such that a vacuum environment created within the transfer region 401, by use of the vacuum pump 454, is maintained during normal operation. It is believed that the use of separate and dedicated pedestal lift assemblies 491, which are configured to accurately position a substrate S and a substrate support 672 in a desirable processing position in each process station 260, and can also be separately and desirably be aligned with the components within the source assembly 470 (e.g., target 472) within the process station 260, has significant advantage over conventional designs that position multiple substrates on a single supporting structure that do not allow separate alignment and adjustments to be made. An example of the importance and issues relating to positioning and alignment of the substrate S to the source assembly 470 components are discussed further below in conjunction with FIGS. 7A and 7B.

The pedestal assembly 492 includes a support plate assembly 494 that is coupled to plate support element 493 that is coupled to the pedestal shaft 492A. The support plate assembly 494, which is dedicated to each processing station 260, is coupled to and actuated by the lift actuator assembly 768 of the pedestal lift assembly 491. The pedestal assembly 492 includes a heater power source 498, an electrostatic chuck power source 499 and a backside gas source 497.

In some embodiments, the support plate assembly 494 includes a plurality of electrical contacts 496 (FIG. 4A) that are disposed on an upper surface of the support plate 494A. The heater power source 498 and electrostatic chuck power source 499 are each electrically coupled to two or more of the electrical contacts 496. The electrical contacts 496 are used to provide electrical power to the one or more electrical elements formed within the substrate support 672 when the substrate support 672 is lifted from the supporting portion 560 of the support arm 308 by the support plate 494A. The electrical contacts 496 are configured to mate with electrical contacts 673 formed on the lower surface of the substrate support 672. In some embodiments, a separate set of electrical contacts 673, which are formed on a lower surface of the substrate support 672, are configured to mate with the electrical contacts 496 of the support plate 494A. In one embodiment, the separate set of electrical contacts 673 are physically separated from the electrical contacts 673 that are configured to mate with the electrical contacts 453 of the support arms 308. In this configuration, the substrate support 672 includes two separate sets of contacts that are each adapted to create a similar electrical connection to the electrical elements (e.g., resistive heating elements, chucking electrodes) embedded within the substrate support 672. The resistive heating elements disposed within the substrate support 672 are coupled to two or more electrical contacts 673 that are in electrical communication with two or more electrical contacts 496 of the support plate 494A that are coupled to the output of the heater power source 498 when the substrate support 672 is positioned in a processing position (FIG. 4B). The one or more chucking electrodes disposed within the substrate support 672 are coupled to two or more electrical contacts 673 that are in electrical communication with two or more electrical contacts 496 of the support plate 494A. In one example, three wires that are coupled to the output of the heater power source 498 and two wires that are coupled to the electrostatic chuck power source 499 are provided through pedestal shaft 492A so that they can be separately connected to their respective mating electrical contact 496. In some embodiments, a reliable separable electrical connection is formed between the electrical contacts 496 and their respective mating electrical contacts 673 due at least in part to a portion of the weight of the substrate support 672 being allowed to cause a surface of the electrical contact 673 to bear against a mating surface of each of the electrical contacts 496 when the substrate support 672 is positioned in the processing position within the process station 260. Thus, allowing a substrate to be chucked and heated by the substrate support 672 while it is positioned on the support plate 494A during processing.

In some embodiments, the support plate assembly 494 includes a separable backside gas connection 495 that is configured to mate with a backside gas receiving surface formed around a backside gas port 671 formed in the backside of the substrate support 672. The backside gas connection 495 is coupled to the backside gas source 497, which is configured to deliver a backside gas (e.g., N₂, He, Ar) to the backside gas port 671 formed in the substrate support 672 that is connected to gas passages formed in the substrate support 672 and to a space formed between a substrate positioned on a substrate receiving surface of the substrate support 672 and the substrate support 672 during processing. The separable backside gas connection 495 is thus configured to be repeatedly sealably connected to the backside gas receiving surface of the substrate support 672 when the substrate support 672 is positioned on the support plate 494A and to be detached from the substrate support 672 when the support plate 494A is in a transfer position (i.e., below the support arm 308). In some embodiments, the separable backside gas connection 495 includes a machined metal or compliant sealing surface that is configured to mate with a polished mating surface of the backside gas receiving surface of the substrate support 672 to form a repeatable gas tight seal that is at least partially formed by a portion of the weight of the substrate support 672 bearing on the surface of the separable backside gas connection 495 when the substrate support 672 is positioned in the processing position within the process station 260. The backside gas connection 495 thus includes a sealing surface that is configured to form a substantially fluid tight seal with the backside gas receiving surface, which is disposed on a surface of the substrate support 672, wherein the separable backside gas connection 495 is configured to be coupled to a backside gas source 497 (FIGS. 4A-4B).

The process kit assembly 480, as shown in FIGS. 4A-4B and 6, generally includes a plurality of processing region components 685 and a sealing assembly 485 that are positioned over and/or within an upper process station openings 734 of the chamber upper wall 616 of the processing module 250. In the process station 260 configuration example disclosed in FIGS. 4A-4B and 6, the processing region components 685 include a base plate 481, process region shield 482, isolation ring 483, station wall 484, cover ring 486, deposition ring 488, and inner shield 489, which together at least partially define the processing region 460 of a process station 260. The base plate 481 is configured to support the process region shield 482, isolation ring 483, station wall 484, sealing assembly 485, cover ring 486, deposition ring 488, and inner shield 489, and allow these components to be positioned on and removed as one assembly from the station opening 713 formed in the upper wall 616 of the processing module 250. The isolation ring 483, which is formed from a dielectric material, is configured to support the target 472 and be position on the station wall 484 that is positioned on the base plate 481. The isolation ring 483 is used to electrically isolate the target 472, when it is biased by the sputtering power supply 475, from the grounded station wall 484.

The process kit assembly 480 also includes a plurality of sealing elements 1001 (e.g., O-rings) that are used to prevent atmospheric gases from entering the processing region 460 during normal processing. Moreover, the source assembly 470 is configured to form a seal with a portion of the process kit assembly 480 by use of a sealing element 1001 and the process kit assembly 480 is configured to form a seal with the upper surface of the chamber upper wall 616 similarly by use of a sealing element 1001 to allow the processing region 460 to be isolated from the external environment during processing.

The station wall 484 includes a first port 484A that is coupled to a vacuum pump 265 and is configured to evacuate the processing region 460 through a circumferential gap formed between an upper portion of the shield 489, lower surface of the target 472 and portion of the isolation ring 483 and station wall 484 during processing. The station wall 484 also includes a second port 484B that is coupled to a gas source 699, and is configured to deliver one or more process gases (e.g., Ar, N₂) to the processing region 460 through a circumferential plenum 484C during processing.

The process region shield 482 is positioned on a lower portion of the station wall 484. The process region shield 482 is typically used to collect deposition sputtered from the target 472, enclose a portion of the processing region 460, and in some configurations, as shown in FIG. 6, support the sealing assembly 485. In this configuration, the process region shield 482 is adapted to form a seal at a surface 484D of the station wall 484 on which it is supported, and similarly form a seal between a surface 485D of the lower plate 485B of the sealing assembly 485 and a lower surface 482A of the process region shield 482. The seals formed between the process region shield 482 and portions of station wall 484 and lower plate 485B can each be formed by use of an O-ring (not shown), welding or other conventional sealing method.

In some embodiments, the sealing assembly 485 includes an upper plate 485A, a lower plate 485B, and a compliant member 485C disposed between the upper plate 485A and lower plate 485B. In some embodiments, as shown in FIG. 6, the compliant member 485C includes a flexible bellows assembly that is configured to be compliant in at least one direction, such as the vertical direction (i.e., Z-direction), and is configured to prevent gases from passing therethrough during processing. The flexible bellows assembly may be a stainless steel or Inconel bellows assembly that is sealably welded at opposing ends to the upper plate 485A and lower plate 485B.

During processing, when the substrate and substrate support 672 are positioned in a processing position below the source assembly 470, as shown in FIG. 4B and 6, a portion of the substrate support 672, or component attached thereto, both of which are referred to herein as a “sealing portion” of the substrate support 672, is adapted to form a “seal” with a portion of the sealing assembly 485 so as to substantially fluidly isolate the processing region 460 from the transfer region 410. Thus, in the process station 260 configuration example disclosed in FIGS. 4A-4B and 6, the substrate support 672, target 472, sealing assembly 485, and plurality of processing region components 685, which include the process region shield 482, station wall 484, and isolation ring 483, substantially enclose and define the processing region 460. In some embodiments, the “seal” formed between the sealing portion of the substrate support 672 and the upper plate 485A of the sealing assembly 485 is created at a sealing region 487 that is formed by physical contact between a surface of the sealing portion of the substrate support 672 and a surface of the portion of the sealing assembly 485. In some lower temperature applications, the seal is formed by use of wiper seal, u-cup seal or an O-ring (not shown) that is positioned at the interface between the surface of the sealing portion of the substrate support 672 and the surface of the portion of the sealing assembly 485. In some high temperature applications, such as at temperatures greater than 200° C., the seal is formed by metal-to-metal, or metal-to-ceramic contact formed at the interface between the sealing portion of the substrate support 672 and the portion of the sealing assembly 485. In some embodiments, the flexible bellows assembly of the sealing assembly 485 is configured to be extended in the vertical direction as the sealing portion of the substrate support 672 is placed in contact with the surface of the portion of the sealing assembly 485 by use of the lift actuator assembly 768 in the substrate support actuation assembly 490. The compliant nature of the flexible bellows assembly allows any misalignment or planarity differences between the surface of the sealing portion of the substrate support 672 and the surface of the portion of the sealing assembly 485 to be taken up so that a reliable and repeatable seal can be formed at the sealing region 487 over many cycles. As illustrated in FIGS. 4A-4D and 6, the substantially parallel orientation/alignment of the sealing portion of the substrate support 672, the sealing portion of the sealing assembly 485, the processing surface of the substrate and the lower surface of the source assembly 470 (e.g., lower surface of the target 472) also allows a repeatable reliable seal to be formed while also allowing the angular alignment between the processing surface of the substrate and lower surface of the source assembly 470 to be easily formed and/or maintained during processing, which is discussed further below in conjunction with FIGS. 7A-7B and 8. Also, as illustrated in FIGS. 4A-4D and 6, the sealing portion of the substrate support 672, the sealing portion of the sealing assembly 485, the processing surface of the substrate, the lower surface of the source assembly 470 (e.g., lower surface of the target 472) and the substrate transfer plane are all in a substantially parallel relationship. By maintaining the substantially parallel relationship between at least the sealing portion of the substrate support 672, the sealing portion of the sealing assembly 485, and the substrate transfer plane during processing and substrate transferring processes, along with the open transfer region 401 volume configuration, provides significant advantages over conventional designs since it reduces the required size of the processing module 250 and system, reduces the number of parts required in the system (e.g., no slit valves), reduce the system complexity and reduces the overall system cost.

However, in some alternate embodiments, the sealing assembly 485 simply comprises a wiper seal, u-cup seal or an O-ring (not shown) that is positioned at the interface between a sealing surface of the substrate support 672 and the lower surface 482A of the process region shield 482 to form a seal therebetween when the substrate support 672 is positioned in the processing position. In this configuration, the portion of the substrate support 672 on which the sealing surface is formed has a diameter that is larger than the inner diameter of the process region shield 482 so that the seal can be formed between the sealing surface and the lower surface 482A while the substrate support is positioned in the processing position during a processing step.

After performing the substrate processing step(s) in a first process station 260, the substrate S and substrate support 672 are lowered so that they are located on the support arm 308. The central transfer robot 245 then rotates the central support 305 about the central axis 253 extending therethrough to swing the support arm 308, substrate S and substrate support 672 through an arc to index the substrate support 672 and substrate S to a position below a second process station 260, where the substrate S is again lifted on the same substrate support 672 by a pedestal lift assembly 491, which is dedicated to that second process station 260, to the processing position. After processing is completed on the substrate S, the substrate S and substrate support 672 are then placed back onto the end of the support arm 308 and transferred to the next process station 260. The processing cycle of raising the substrate S and substrate support 672, processing the substrate S, lowering the substrate S and substrate support 672 and transferring the substrate support 672 and substrate S can then repeated multiple times.

During the substrate S and substrate support 672 transferring sequence within the processing module 250, the processing regions 460 of each of the process stations 260 are in direct communication with the transfer region 401. This structural design, while reducing system cost due to the removal of the need for dedicated slit valves isolating each process station from a transferring region found in more conventional designs and thus also reducing substrate transfer overhead time (i.e., increasing throughput) due to the reduced number of steps required to transfer a substrate, also allows the pressures between the processing regions 460 and transfer region 401 to be equilibrated and a desired base pressure to be more easily and rapidly achieved across the processing module 250. The system design disclosed herein also reduces the complexity and cost by eliminating the need for separate processing chamber structures (e.g., separate welded compartments) and supporting hardware (e.g., individual support frame, slit valve, etc.) needed in conventional processing system designs. Moreover, this design and transfer sequence also provides additional advantages since the processing regions 460 of each process station 260 can be separately and selectively isolated by controlling the movement and position of the substrate support 672 by the substrate support actuation assembly 490 positioned at each process station 260 based on commands sent from the system controller 299 (FIG. 2A). For example, it may be desirable to separately process a substrate in process stations 260A and 260B by positioning the substrates S and substrate supports 672 in processing positions within these process stations, while process stations 260C, 260D, 260E and 260F remain in a non-isolated state due to the substrate supports 672 at these positions remaining in a transfer position and thus allowing the fluid communication between the processing regions 460 and the transfer region 401 at these process stations.

### Alternate Process Station Configuration(s)

FIGS. 4C-4D are schematic cross sectional views of a processing module 250 that includes an alternately configured version of process station 260F, according to an embodiment. In this configuration, the processing module 250 includes an alternately configured central transfer robot 245 that includes a plurality of support arms 309 that are configured to transfer and deposit one or more substrates onto a substrate support surface 591A of a support chuck assembly 590. The substrate support surface 591A is formed on the support chuck assembly 590 that is attached to the pedestal lift assembly 491.

FIG. 4C illustrates the support chuck assembly 590 that is positioned in a substrate receiving position or substrate transfer position. FIG. 4D illustrates the support chuck assembly 590 while it is positioned in a substrate processing position. The support chuck assembly 590 configurations illustrated in FIGS. 4C-4D illustrate a design in which a substrate supporting element 591 of the support chuck assembly 590 remains attached to the pedestal lift assembly 491 components such that it is dedicated to a single process station 260, and is limited to moving a substrate vertically, such as moving the substrate between the substrate receiving position and the processing position.

The support chuck assembly 590 includes a plate support 594, which is configured to support and retain the substrate supporting element 591 and is coupled to a pedestal shaft 592A. The support chuck assembly 590 includes a heater power source 498, an electrostatic chuck power source 499 and a backside gas source 497. The heater power source 498 and/or electrostatic chuck power source 499 are each electrically coupled the one or more electrical elements formed within the substrate supporting element 591. In this configuration, the body of the substrate supporting element 591 includes one or more resistive heating elements embedded therein. The resistive heating elements are disposed within the body of the substrate supporting element 591 and are in electrical communication with the output connections of the heater power source 498. The one or more chucking electrodes disposed within the body of the substrate supporting element 591 are in electrical communication with the chucking power supply 499. In one example, three wires that are coupled to the output of the heater power source 498 and two wires that are coupled to the electrostatic chuck power source 499 are provided through pedestal shaft 592A so that they can be separately connected to their respective electrical elements.

The support chuck assembly 590 includes a backside gas port 595 formed in the substrate supporting element 591. The backside gas port 595 is coupled to the backside gas source 497, which is configured to deliver a backside gas (e.g., N₂, He, Ar) to gas passages formed in the substrate supporting element 591 and to a space formed between a substrate and the surface of the substrate supporting element 591 during processing.

As similarly discussed above, during processing, when the substrate and support chuck assembly 590 are positioned in a processing position below the source assembly 470 (FIG. 4D), a portion of the support chuck assembly 590, or component attached thereto, includes a sealing surface 596 that is adapted to form a “seal” with a portion of the sealing assembly 485 so as to substantially fluidly isolate the processing region 460 from the transfer region 410. In some embodiments, the “seal” formed between the sealing surface 596 and the upper plate 485A of the sealing assembly 485 is created within the sealing region 487 by the physical contact created between a surface of the sealing surface 596 and a surface of the portion of the sealing assembly 485. As similarly discussed above, in some lower temperature applications, the seal is formed by use of wiper seal, u-cup seal or an O-ring (not shown) that is positioned at the interface between the sealing surface 596 of the support chuck assembly 590 and the surface of the portion of the sealing assembly 485. Also, in some high temperature applications, such as at temperatures greater than 200° C., the seal is formed by metal-to-metal, or metal-to-ceramic contact formed at the interface between the portion of the sealing surface 596 of the support chuck assembly 590 and the portion of the sealing assembly 485.

Referring to FIG. 4C, the central transfer robot 245 includes a plurality of support arms 309 that are configured to pick-up and deposit one or more substrates onto the substrate support surface 591A of a support chuck assembly 590. In one embodiment, the central transfer robot 245 includes a lift mechanism (not show) that is configured to at least raise and lower the central support 305 and plurality of support arms 309 attached thereto from a transfer position to a substrate drop off position, which is below the transfer position. The support arm 309 is similarly mounted, shaped and configured as the support arm 308 described above, except that it is configured to transfer substrates between process stations 260, versus substrates and substrate supports 672 between process stations 260. In one embodiment, each support arm 309 includes a plurality of substrate supporting elements 309A that are positioned on an underside surface of the support arm 309 so that a substrate supported on the supporting surface 309C of the substrate supporting elements 309A can be positioned directly on the supporting surface 591A of the substrate supporting element 591. The inner edges 309B of opposing substrate supporting elements 309A are positioned a distance apart that is less than the smallest possible outer dimension of the substrate to assure that all possible substrates can be received and transferred by the support arm 309. A cut-out (not shown) in the upper surface and upper portion of the substrate supporting element 591 is configured to mate with the orientation of the substrate supporting elements 309A so that the substrate supporting elements 309A do not contact or interfere with the substrate supporting element 591 after the substrate is disposed on the supporting surface 591A and so that the support arm can be rotated about the central axis 253 to move the support arm 309 to a position that is not over the support chuck assembly 590.

A similar robot arm configuration, or end of a robotic arm, as the substrate supporting elements 309A portion of the support arm 309 may also be utilized as part of the end effector of the intermediate robot 285A, 285B to pick-up and drop-off substrates on the supporting surface 591A of the substrate supporting element 591, or alternately the supporting surface 674 of the body 643 of the substrate support 672. Similarly, as discussed above, in one embodiment, the intermediate robot 285A, 285B includes a lift mechanism (not show) that is configured to at least raise and lower the end effector (not shown) of the intermediate robot 285A, 285B to and from a transfer position and a substrate drop off position, which is below the transfer position. One or more cut-outs (not shown) in the upper surface and upper portion of the substrate supporting element 591, or substrate support 672, is configured to mate with the orientation of the substrate supporting elements 309A positioned on the end effector (not shown) of the intermediate robot 285A, 285B so that the substrate supporting elements 309A do not contact or interfere with the substrate supporting element 591 or substrate support 672 after the substrate is disposed thereon and the end effector is retracted from a position that is not over the support chuck assembly 590 or substrate support 672.

Processing systems 200 that include the use of robot end effectors that have supporting elements like the supporting elements 309A illustrated in FIG. 4C have been found to be useful since they allow substrates to positioned on the substrate supporting surface of the substrate support 672 or support chuck assembly 590 without the need for the use of a separate substrate lift assembly (e.g., lift pins, lift hoop and lift actuator) commonly used in the art to separate a substrate from the substrate supporting surface during substrate exchange operations. While reducing the cost and complexity of the process stations 260, use of this type of robot end effector also removes the need to form holes within the substrate support 672 or support chuck assembly 590 that are required to allow the lift assembly components (e.g., lift pins) access the substrate disposed on the substrate receiving surface, and then also removes the need to seal the holes formed in the substrate support 672 or support chuck assembly 590 in an effort to fluidly isolate the processing region 460 from the transfer region 401 during processing. Therefore, in one or more of the embodiments described herein, the substrate support 672, or support chuck assembly 590, does not include through holes used to accept substrate lift components (e.g., lift pin holes), and may in some cases only include a single through hole used to provide a backside gas to a substrate during processing, such as the backside gas port 671, or backside gas port 595.

While the alternate process station configuration illustrated in FIGS. 4C-4D includes a substrate transferring sequence that does not include the movement of the substrate support with the substrate, the processing module 250 in this case still includes the same basic transfer region 401 and processing region 460 structural configuration and advantages described above. For example, the processing regions 460 of each process station 260 can be separately and selectively isolated by controlling the movement and position of the support chuck assembly 590 by the substrate support actuation assembly 490 at each process station 260 based on commands sent from a system controller 299 (FIG. 2A).

### Substrate Processing Examples

As discussed above in conjunction with FIGS. 1A and 1B, each process station 260A-260F is configured to separately perform a desired process on a substrate. In one example, a deposition process is separately performed in a plurality of process stations within the processing module 250. The separately performed deposition process may include sequentially depositing, via a PVD process, a layer on a substrate as it is sequentially processed in process stations 260A-260F. During a PVD deposition process, or sputtering process, a bias is applied to the target 472 by the power supply 475. The bias applied to the target causes a portion of the target material to be ejected from the face of the target 472 due to ionized gas atoms, formed by the applied bias delivered to a sputtering gas provided from the gas source 699, bombarding the surface of the target. The flux of the ejected, or sputtered material, includes ionized and neutral atoms of target material that generally travel towards the lower portion of the formed processing region 460, and to the surface of the substrate S and shields (e.g., inner shield 489, process region shield 482) of the process kit assembly 480. The direction of the flux of the ionized target atoms ejected from the surface of the target 472 can be altered by grounding, applying a direct current (DC) or radio frequency (RF) bias to one of the electrodes formed in the substrate support 672. Thus, in some embodiments, the heater power source 498 and electrostatic chuck power source 499 include a DC or RF power supply that is configure to apply a bias to the one or more chucking electrodes or heating element(s) disposed within the substrate support 672. The chucking electrodes disposed within the substrate supporting element 591 are generally positioned just below (e.g., 0.1 mm-1 mm) the dielectric material disposed at the substrate supporting surface of the substrate support 672. However, due to the inability to ionize all of the sputtered atoms during processing and the structural configuration of the PVD chamber, a PVD process is considered to be a line-of-sight deposition process, which from a within-wafer (WIW) deposition uniformity perspective, is affected by the shape of the target and parallelism of the target 472 to the surface of the substrate during the PVD deposition process. In one example, a smaller target-to-substrate spacing at one edge of a substrate relative to an opposing edge of a substrate will cause a thickness variation across the substrate due to the angular misalignment. Therefore, as is discussed below in relation to FIGS. 7A-7B, the distortion of the chamber upper wall 616 and lower wall 618, due to the pressure difference created between an external ambient pressure region 403 (FIG. 4A) and the transfer region 401 and processing region 460, tend to cause the surface of the target 472 to deflect and become angled relative to the surface of the substrate support 672 during processing versus when a vacuum pressure is not provided within the transfer region 401 and processing region 460, such as occurring during maintenance activities. The deflection of the targets 472 within each of the process stations 260 also increases as the size of the processing module 250 increases as substrate sizes increase (e.g., 300 mm), due to the large overall span the chamber upper wall 616 and lower wall 618 need to extend within the X-Y plane (e.g., >3 m diameter) to allow the substrates to be positioned within the transfer region 401 and transferred between the process stations 260. In an effort to minimize the effect of distortion of the chamber upper wall 616 and lower wall 618, a structural support assembly 710 is used to minimize the distortion of the chamber upper wall 616 and lower wall 618 and improve the parallelism of the source assemblies 470 of the process stations 260A-260F to each other whether the processing module 250 is under vacuum (e.g., 10 Torr to 10⁻⁸ Torr) or at ambient pressure (e.g., 760 Torr).

After performing the PVD processing steps in the process station 260, the bias voltage on the target 472 is returned to zero, the generated plasma dies out, and, as discussed above in conjunction with the embodiments illustrated in FIGS. 4A and 4B, the substrate S and substrate support 672 is lowered to be located back on the support arm 308.

In addition to the deposition processes one or more target pasting processes (e.g., cleaning an oxide layer or a reactive sputtering formed layer off of the surface of the target) and/or a chamber clean process can additionally be performed in a process station. In one example, during a pasting process a pasting disk (e.g., a substrate sized metal disk) is positioned on the pedestal lift assembly 491 and moved into a processing position by the pedestal lift assembly 491 to allow a PVD deposition process to be performed on the pasting disk instead of a substrate to clean the surface of the target 472.

### Processing Module Structural Elements

Referring now to FIGS. 7A, 7B and 8, further structure and details of the processing module 250 are shown. Here, as shown in FIG. 7A, processing module 250 includes a lower monolith 720 forming the lower portion or base of the processing module 250, and an upper monolith 722 that is sealed thereto and supported thereon. In some embodiments, lower monolith 720 and the upper monolith 722 are welded, brazed or fused together by some desirable means to form a vacuum tight joint at the interface between the lower monolith 720 and the upper monolith 722. In some embodiments, the lower monolith 720 has a generally plate like structure that has seven side facets (FIG. 2A), and includes the lower wall 618 that includes a central opening 723 disposed within a central recess 724 (FIG. 8) disposed within a central region, and a plurality of lower process station openings 725 (two shown in FIG. 8), each corresponding to the location of a process station 260. A plurality of pedestal assemblies 492, two of which are shown in FIG. 8, extend through and downwardly from the lower wall 618. A lower supporting structure 727, which includes a support frame 728, is used to support the lower monolith 720 and the upper monolith 722 and position the processing module 250 at a desired vertical position above a floor (not shown).

In some embodiments, the upper monolith 722 has a generally plate like structure that has eight side facets (FIG. 2A) that match those of the lower monolith 720. An upper main portion 711, which includes the chamber upper wall 616, includes a central opening 713 (FIG. 8) disposed within a central region, and a plurality of upper process station openings 734 (FIGS. 4A-4D, 7B and 8), each corresponding to the location where the process kit assembly 480 and source assembly 470 of the process station 260 are positioned. It has been found that forming a central opening 713 in the chamber upper wall 616 such that the diameter of the central opening 713 falls within a diameter ratio, which is defined by a ratio of the diameter of the central opening to a diameter of the outer extent of transfer region 401 at the inner surface 721A of the outer region 721 (i.e., unsupported length of the chamber upper wall 616), to less than about 0.5 and greater than 0.3 allows user accessibility to the central region of the processing module 250 through the central opening 713 and surprisingly not adversely increasing the distortion of the chamber upper wall 616 during processing (e.g., under vacuum) due to the material removed from the center of the chamber upper wall 616. In this configuration, the removable central cover 690 extends over the central opening 713, but is generally not coupled to or used to provide additional structural support to the chamber upper wall 616. The removable central cover 690 includes a seal (not shown) that prevents the external environmental gases from leaking into the transfer region 401 when the transfer region 401 is maintained in a vacuum state by the vacuum pump 454. The inner surface 721A of a perimeter region 721 of the lower monolith 720 and the upper monolith 722 forms the outer edge of the transfer region 401. The access openings 504A, 504B extend through a portion of the inner surface 721A and through either a portion of a wall of the upper monolith 722 (FIG. 4A-4D) or a portion of a wall of the lower monolith 720 (not shown).

As discussed above, the distortion of the chamber upper wall 616 and lower wall 618, due to the pressure difference created between an ambient pressure region 403 and the transfer region 401 and processing region 460, tends to cause the portions of the source assemblies 470 (e.g., surfaces of the targets 472) to deflect and become angled relative to the surface of the substrate support 672 during processing. In an effort to minimize the distortion of the chamber upper wall 616 and lower wall 618, a structural support assembly 710 is used to minimize the distortion of the chamber upper wall 616 and/or lower wall 618 and improve the parallelism of the source assemblies 470 whether the processing module 250 is under vacuum or at ambient pressure. Due to manufacturing limitations, cost limitations and limitations regarding the shipment of the assembled upper monolith 722 and lower monolith 720, the chamber upper wall 616 typically has an average wall thickness (Z-direction) that is between 50 millimeters (mm) and 100 mm, and also to the lower wall 618 has an average wall thickness (Z-direction) that is between 75 mm and 150 mm. Here, to help ensure this parallelism, the upper monolith 722 includes the structural support assembly 710 that includes an upper support element 701 and a plurality of mounting elements 702 that each have a first end that is coupled to the chamber upper wall 616. In some embodiments, the first end of the mounting elements 702 are coupled to the chamber upper wall 616 by bolting, welding, or even integrally forming the mounting elements 702 as part of the chamber upper wall 616. The array of mounting elements 702 are positioned on and coupled to the chamber upper wall 616 between each of the process stations 260. In some embodiments, the array of mounting elements each have a first end that is coupled to the first wall at a radial position that is positioned on a radial direction 735 that extends between two adjacent process station openings. In one example, as shown in FIG. 7B, the radial position of each of the mounting elements is positioned along a radial direction 735 that extends between each pair of process station openings and are positioned at a radial position that is inboard (e.g., smaller radius extending from the central axis 253) of the upper process station openings 734. In some configurations, the mounting elements 702 include a vertical section 714A (FIG. 8) and also a radial section 714B (FIG. 7B), which extends in a radial direction from the central axis 253.

In some embodiments, the upper support element 701 generally comprises a toroidal shaped structural element that is coupled to a second end of each of the mounting elements 702 to minimize the deflection of the chamber upper wall 616. As shown in FIGS. 7A-7B, in some configurations, the toroidal shape is not a perfect toroid and can include one or more facets (e.g., six facets shown) and one or more planar mounting surfaces (e.g., top and bottom surfaces). The upper support element 701 is coupled to each of the mounting elements 702 by bolting (i.e., bolts 703), welding, or even integrally forming the mounting elements 702 as part of the upper support element 701. The vertical section 714A of the mounting elements 702 is configured to position the upper support element 701 a distance 808 between about 150 mm and about 450 mm from the mounting surface (e.g., exposed top surface) of the chamber upper wall 616. The cross-section of the upper support element 701, as shown in FIG. 8, includes a cross-sectional height 806 and cross-sectional width 807 that is configured provide a desired added stiffness to the chamber upper wall 616, due to at least to its area moment of inertia, to support the chamber upper wall 616 and counteract the applied vacuum pressure (e.g., −14.7 psig) induced load to minimize the distortion thereof. In one example, a three meter diameter chamber upper wall 616 receives a total of about 716,000 N (161,000 lbs) of force due to the vacuum pressure applied during processing due to the transfer region 401 being maintained, for example, at a pressure less than 1 Torr, such as between 10⁻⁸ Torr to 10⁻⁸ Torr. In some embodiments, the upper support element 701 and the mounting elements 702 are formed from the same material as the material used to form the upper monolith 722 and lower monolith 720 components (e.g., chamber upper wall 616 and lower wall 618), such as an aluminum material (e.g., 6061 Al). In some embodiments, the upper support element 701 and the mounting elements 702 are formed from a material that has a modulus of elasticity (E) that is greater than the material used to form the upper monolith 722 and lower monolith 720 components, such as an stainless steel material (e.g., 304 SST, 316 SST) and the upper monolith 722 and lower monolith 720 components are formed from an aluminum material. In one example, the upper support element 701 has a cross-sectional height 806 that is between about 50 mm and about 125 mm, a cross-sectional width 807 that is between about 75 mm and about 200 mm and has a central opening 805 that has an inner diameter that is between about 750 mm and about 900 mm. In this configuration the upper support element 701 is configured to withstand a vacuum induced load provided to the chamber upper wall 616 that includes a central opening 713 in the chamber upper wall 616 that has a diameter that is less than the inner diameter of the central opening 805, such as less than 85% of the inner diameter of the central opening 805, or less than 95% of the inner diameter of the central opening 805. In some embodiments, the combination of the structural support assembly 710 and the structure of the chamber upper wall 616 is configured minimize the angular deflection, or angular misalignment, of the processing surface 472A of a targets 472, relative to a lateral plane 801 (FIG. 8) that is parallel to the X-Y plane, to a tilt angle of between about 0.1 mm and about 0.25 mm measured edge-to-edge (e.g., rise) across a 300 mm diameter (e.g., run) that is centered about the center of a target 472 (e.g., between about 0.02 and 0.05 degree angle). In some embodiments, the combination of the structural support assembly 710 and the structure of the chamber upper wall 616 is configured minimize the angular misalignment of the processing surface 472A of a targets 472 relative to the exposed surface of a substrate S, disposed on a substrate support 672, to a tilt angle of between about 0.1 mm and about 1 mm measured edge-to-edge (e.g., rise) across a 300 mm diameter (e.g., run) of the substrate S (e.g., between about 0.02 and 0.2 degree angle). While not intending to be limiting as to the scope of the disclosure provided herein, in some cases, the angular misalignment between processing surface 472A and the lateral plane 801 can be the greatest along a radial direction extending from the central axis due to the deflection of the chamber upper wall 616 (e.g., 1^{st} bending mode shape).

While not shown in FIG. 8, in some embodiments, a second structural support assembly 710 is coupled to the lower wall 618 in a similar fashion as the structural support assembly 710 is coupled to the chamber upper wall 616. Thus, in some embodiments, the processing module 250 may include a first structural support assembly 710 on the chamber upper wall 616 and a second structural support assembly 710 on the lower wall 618 to improve the parallelism of the source assemblies 470 in all of the process stations 260 whether the transfer region 401 within the processing module 250 is under vacuum or at ambient pressure.

### Alternate Processing Module Configuration Example

FIGS. 9A and 9B illustrate an example of an alternate configuration of a processing module 250 that includes four process stations versus the six process station configurations primarily described above. Thus, FIGS. 9A and 9B, illustrate a further processing module concept, which is a paddle robot processing module 900. In this configuration, four process stations 260 are provided, each having the same general configuration of the process stations 260 of FIGS. 2A-8 hereof, but in contrast, the four process stations are located the four corners of a rectangular enclosure 902 and the substrate supports 672A-672D do not move from one process station 260 to another process station 260, as similarly described in conjunction with FIGS. 4C-4D. The rectangular enclosure 902 includes an upper body 904 and a lower body 906 that are configured in a similar fashion as the upper monolith 722 and the lower monolith 720, which are described above. FIG. 9A includes the upper body portion 904 and the lower body 906 of the paddle robot processing module 900, and FIG. 9B only includes the lower body 906 portion of the paddle robot processing module 900. The upper body 904 includes a chamber upper wall that is configured to support the source assembly 470 and the process kit assembly 480 of each of the process stations 260A-260D. The lower body 906 similarly includes a lower wall that is configured to support the support chuck assemblies 590 within each of the process station 260A-260D

First and second process chamber valves 244A, 244B are located on a common one of the four walls of the paddle robot processing module 900, such that a substrate may be loaded therethrough and onto a first substrate support 672A using a robot, such as the intermediate robot 285 of FIG. 2A. Thence, the substrate support 672A is lifted to the processing position in the first process station 260A and the substrate is processed, such as by depositing a sputtered film layer thereon. Then, the substrate may be moved by a first paddle robot 908A from substrate support 672A to substrate support 672B for processing at the next process station 260B. Alternatively, a first substrate can be loaded onto the first substrate support 672A, and then moved by first paddle robot 908A to the second substrate support 672B, without being processed on the first substrate support 672A, and then a second substrate is loaded onto the first substrate support 672A for processing thereon. In a similar fashion, a second paddle robot 908B can move two additional substrates between a fourth substrate support 672D and a third substrate support 672C. The processing performed on the first and second substrates in their respective process stations, and in some cases additionally on the additional substrates in their respective process stations, can be performed simultaneously or substantially simultaneously.

Each paddle robot 908A, 908B includes a rotatable base 910A, 910B, from which extends a paddle arm 912A, 912B terminating in a paddle end effector 914A, 914B. The rotatable bases 910A, B are connected to a motor (not shown) below the rectangular enclosure, and are rotatable to position the paddle end effectors 914A, 914B over one of the respective substrate supports 672A-D. Additionally, rest stations 916A-D are positioned along the arcuate paths 995 through which the paddle end effectors 914A, 914B swing, such that a substrate may be stored at a rest station 916A-D between processing at process stations 260 or directly between the process stations 260.

The invention has been described above with reference to specific embodiments. Persons skilled in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

What is claimed is:

1. A substrate processing system, comprising:
a processing module comprising a plurality of walls that at least partially define a transfer region, wherein the plurality of walls comprise:
a first wall that comprises an array of process station openings that surround a central axis; and
a second wall comprising a central opening, wherein the second wall is positioned on a side of the processing module that is opposite to the first wall;
two or more process stations positioned on the first wall, wherein each process station of the two or more process stations is separately disposed over a process station opening and comprises:
a source assembly;
a process kit assembly that comprises a plurality of processing region components and a sealing assembly; and
a substrate support actuation assembly that comprises a support plate assembly that is positionable by an actuator that is coupled to the second wall;
a central robot that is configured to transfer substrates within the transfer region, and comprises:
a plurality of support arms that are coupled to a central support at a first end, and include a supporting region at a second end; and
an actuator configured to rotate the central support and the plurality of support arms about the central axis,
wherein the supporting region of each support arm is positionable below a process station opening as the support arm is rotated about the central axis; and
a plurality of substrate supports that each comprise a sealing surface and a body that has a substrate receiving surface and one or more electrical elements disposed therein,
wherein
a substrate support is disposed on a supporting region of each of the support arms when substrates are being transferred in the transfer region by the central robot, and
the substrate support is disposed on a support plate assembly, and separated from the supporting region of the support arm, when a substrate is positioned in a processing position within a process station of the two or more process stations by the actuator.

2. The substrate processing system of claim 1, wherein at least one of the source assemblies in the two or more process stations comprise a physical vapor deposition (PVD) target.

3. The substrate processing system of claim 2, wherein a source assembly in one of the two or more process stations comprises a showerhead.

4. The substrate processing system of claim 1, wherein the sealing surface is configured to form a seal with a surface of the sealing assembly when the substrate support is positioned in the processing position, wherein the formed seal is configured to fluidly isolate a processing region from the transfer region.

5. The substrate processing system of claim 1, wherein the sealing assembly further comprises:
a first plate, a second plate and a compliant member that is coupled to the first plate and the second plate,
wherein a surface of the first plate is configured to contact the sealing surface when the substrate support is positioned in the processing position, and a surface of the second plate is coupled to and forms a seal with one of the plurality of processing region components.

6. The substrate processing system of claim 5, wherein the surface of the first plate is substantially parallel to the lower surface of the source assembly when the surface of the first plate is in contact with the sealing surface.

7. The substrate processing system of claim 1, wherein
the supporting region of each support arm further comprises a plurality of support arm electrical contacts that are configured to be electrically coupled to a power source,
the substrate support further comprises a plurality of substrate support electrical contacts that are electrically coupled to the one or more electrical elements, and
the plurality of support arm electrical contacts are each configured to contact a different electrical contact of the substrate support electrical contacts when the substrate support is disposed on a supporting region of a support arm of the plurality of support arms.

8. The substrate processing system of claim 1, wherein a substrate support of the plurality of substrate supports is disposed on a support plate that is coupled to the actuator when the substrate support is transferred from the supporting region of a support arm of the plurality of support arms to the process position by the actuator, wherein the support plate is positioned in the transfer region and below the plurality of support arms when the substrates are being transferred in the transfer region by the central robot.

9. The substrate processing system of claim 1, wherein a substrate support of the plurality of substrate supports is disposed on a support plate that is coupled to the actuator when the substrate support is transferred from the supporting region of a support arm of the plurality of support arms to the process position by the actuator, wherein
the substrate support further comprises a plurality of substrate support electrical contacts that are electrically coupled to the one or more electrical elements, and
the support plate comprises a plurality of support plate electrical contacts that are each configured to contact a different electrical contact of the substrate support electrical contacts when the substrate support is disposed on the support plate.

10. The substrate processing system of claim 9, further comprising:
a separable gas connection that comprises a sealing surface that is configured to form a substantially fluid tight seal with a receiving surface disposed on a surface of a substrate support of the plurality of substrate supports, wherein the separable gas connection is configured to be coupled to a gas source.

11. A substrate processing system, comprising:
a processing module comprising a plurality of walls that at least partially define a transfer region, wherein the plurality of walls comprises:
a first wall that comprises a first central opening and an array of process station openings that surround the first central opening; and
a second wall comprising a second central opening, wherein the second wall is positioned on a side of the processing module that is opposite to first wall;
two or more process stations positioned on the first wall, wherein each process station of the two or more process stations is separately disposed over a process station opening and comprises:
a source assembly that comprises a processing surface that is adjacent to a processing region of the process station and is positioned in a parallel relationship to a horizontal plane; and
a structural support assembly comprising:
a support element having a toroidal shape and mounting surface; and
an array of mounting elements that are disposed between the supporting element and the first wall of the processing module, and each comprises:
a first end that is coupled to the first wall at a radial position on a radial line that extends between two adjacent process station openings of the array of process station openings, and
a second end that is coupled to the mounting surface of the support element,
wherein the structural support assembly reduces the deflection of the first wall and angular misalignment of the processing surface to the horizontal plane when a vacuum pressure is generated in the transfer region.

12. The substrate processing system of claim 11, wherein the source assembly further comprises a physical vapor deposition (PVD) target, and the processing surface is defined by a surface of the physical vapor deposition (PVD) target.

13. The substrate processing system of claim 11, wherein the source assembly further comprises a showerhead, and the processing surface is defined by a surface of the showerhead.

14. The substrate processing system of claim 11, wherein the plurality of walls of the processing module comprises an aluminum material, and the support element and array of mounting elements comprise an aluminum material.

15. The substrate processing system of claim 11, wherein the plurality of walls of the processing module comprises an aluminum material, and the support element and array of mounting elements comprise a material that has a higher modulus of elasticity than the aluminum material.

16. The substrate processing system of claim 11, wherein the support element has an inner diameter that is larger than the diameter of the first central opening.

17. The substrate processing system of claim 11, wherein the mounting surface of the support element is spaced a first distance from the first wall, wherein the first distance is substantially equal to the distance between the first end and the second end.

18. The substrate processing system of claim 11, wherein
the two or more process stations further comprise:
a process kit assembly that comprises a plurality of processing region components and a sealing assembly; and
a substrate support actuation assembly that comprises a support plate assembly that is positionable by an actuator that is coupled to the second wall; and
the substrate processing system further comprises:
a plurality of substrate supports that each comprise a sealing surface and a body that has a substrate receiving surface and one or more electrical elements disposed therein, wherein the sealing surface is configured to form a seal with a surface of the sealing assembly when the substrate support is positioned in a processing position, wherein the formed seal is configured to fluidly isolate a processing region from the transfer region.

19. The substrate processing system of claim 18, wherein the sealing surface of the substrate support is substantially parallel to the processing surface of the source assembly and the transfer plane.

20. A substrate processing system, comprising:
a processing module comprising a plurality of walls that at least partially define a transfer region, wherein the plurality of walls comprises:
a first wall that comprises a first central opening and an array of upper process station openings that surround the first central opening; and
a second wall comprising a second central opening and an array of lower process station openings that surround the second central opening, wherein the second wall is positioned on a side of the processing module that is opposite to first wall;
a central robot comprising:
a central support that is positioned over the second central opening and within the transfer region;
a plurality of support arms that are coupled to central support and extend from the central support in a radial direction that extends from a central axis; and
an actuator configured to rotate the central support and the plurality of support arms about the central axis;
two or more process stations positioned on the first wall, wherein each process station is disposed over one of the upper process station openings and comprises:
a source assembly; and
a process kit assembly that comprises a plurality of processing region components and a sealing assembly; and
a substrate support actuation assembly that comprises an actuator that is coupled to the second wall; and
a substrate support comprising a body that has a substrate receiving surface and one or more electrical elements disposed therein, and the substrate support is configured to be transferred from a transfer position to a process position by use of the actuator of the substrate support actuation assembly, wherein the transfer position is positioned below the plurality of support arms and the process position is positioned above the plurality of support arms.

21. The substrate processing system of claim 20, wherein at least one of the source assemblies in the two or more process stations comprise a physical vapor deposition (PVD) target.

22. The substrate processing system of claim 21, wherein a source assembly in one of the two or more process stations comprises a showerhead.

23. The substrate processing system of claim 20, wherein a sealing surface formed on the substrate support is configured to form a seal with a surface of the sealing assembly when the substrate support is positioned in the processing position, wherein the formed seal is configured to fluidly isolate a processing region from the transfer region.

24. The substrate processing system of claim 20, wherein the sealing assembly further comprises:
a first plate, a second plate and a compliant member that is coupled to the first plate and the second plate,
wherein a surface of the first plate is configured to contact a sealing surface formed on the substrate support when the substrate support is positioned in the processing position, and a surface of the second plate is coupled to and forms a seal with one of the plurality of processing region components.

25. The substrate processing system of claim 24, wherein the surface of the first plate is substantially parallel to the lower surface of the source assembly when the surface of the first plate is in contact with the sealing surface.
